(19) United States
(12) Patent Application Publication
(10) Pub. No.: US 2025/0143192 A1
(43) Pub. Date: May 1, 2025

(54) STACKED FILM, MAGNETORESISTIVE EFFECT ELEMENT, SEMICONDUCTOR MEMORY AND LOGIC LSI

(71) Applicant: TOHOKU UNIVERSITY, Sendai-shi (JP)

(72) Inventors: Yoshiaki Saito, Sendai-shi, Miyagi (JP); Shoji Ikeda, Sendai-shi, Miyagi (JP); Tetsuo Endoh, Sendai-shi, Miyagi (JP); Hirofumi Inoue, Sendai-shi, Miyagi (JP)

(73) Assignee: TOHOKU UNIVERSITY, Sendai-shi (JP)

(21) Appl. No.: 18/927,336

(22) Filed: Oct. 25, 2024

(30) Foreign Application Priority Data
Oct. 27, 2023 (JP) 2023-185119

(51) Int. Cl. H10N 50/85; C22C 5/04; H01F 10/32; H10B 61/00; H10N 50/10

(52) U.S. Cl. CPC H10N 50/85; C22C 5/04; H01F 10/3268; H10B 61/20; H10N 50/10

(57) ABSTRACT

There is provided a stacked film with strong interlayer exchange coupling strength for upper and lower two magnetic layers, a magnetoresistive effect element, a semiconductor memory, and a logic LSI. A stacked film 10 includes a first magnetic layer 11, an antiferromagnetic coupling layer 12 adjacent to the first magnetic layer, and a second magnetic layer 13 adjacent to the antiferromagnetic coupling layer and antiferromagnetically coupled to the first magnetic layer. The antiferromagnetic coupling layer 12 includes a layer containing an Ir—Re alloy and has an atom proportion of Re in the Ir—Re alloy of more than 0% and 12.5% or less. The magnetoresistive effect element, the semiconductor memory, and the logic LSI include one or a plurality of the stacked films.

### CROSS-REFERENCE TO RELATED APPLICATION

This application claims the benefits of Japanese Patent Application No. 2023-185119, filed on Oct. 27, 2023, the entire disclosures of which are incorporated by reference herein.

### TECHNICAL FIELD

The present invention relates to a stacked film, a magnetoresistive effect element, a semiconductor memory, and a logic LSI.

### BACKGROUND ART

In a magnetic tunnel junction (MTJ) element, an interlayer antiferromagnetic (a synthetic anti-ferromagnetic) coupling layer is used as a pin layer in which the direction of magnetization is fixed. In the MTJ element, an STT-magnetic random access memory (MRAM), which rewrites data in a recording layer using a spin injection magnetization reversal (a spin transfer torque: STT), and an SOT-MRAM, which rewrites data in a recording layer using spin-orbit torque (SOT) induced magnetization reversal, have been known. In addition, it has also been proposed that an interlayer antiferromagnetic coupling layer be used as a conductive layer in a SOT-MRAM element.

Using a perpendicular magnetized material for a magnetic material allows an element to be smaller in size and higher in density for placement than using an in-plane magnetized magnetic material and can improve storage capacity. However, it has been known that thermal stability deteriorates when perpendicular magnetic anisotropy is small. In Non-Patent Literature 1 and Non-Patent Literature 2, a problem is disclosed in which small coupling strength between ferromagnetic layers in an STT-MRAM increases write errors due to back-hopping.

Patent Literature 1 discloses that an Ir layer or an Ru layer is used as an interlayer antiferromagnetic coupling layer. As the element size is miniaturized, the stability of a pin layer deteriorates, therefore increasing write errors due to back-hopping. Accordingly, an interlayer antiferromagnetic coupling layer having stronger exchange coupling strength than the Ir layer or the Ru layer is required.

### CITATION LIST

### Patent Literature

Patent Literature 1: Japanese Unexamined Patent Application Publication No. 2022-33026

### Non-Patent Literature

Non-Patent Literature 1: W. Kim et al., IEEE Trans. Magn. 52, 3401004 (2016)
Non-Patent Literature 2: T. Devolder et al., Phys. Rev. B 102, 184406 (2020)

### SUMMARY OF INVENTION

### Technical Problem

Thus, a stacked film with strong coupling strength is required for upper and lower two magnetic layers having perpendicular magnetic anisotropy.

Therefore, an object of the present invention is to provide a stacked film with strong interlayer exchange coupling strength for upper and lower two magnetic layers, and a magnetoresistive effect element, a semiconductor memory, and a logic LSI that include the stacked film.

### Solution to Problem

The present invention has the following concepts.

A stacked film including:

[1]
a first magnetic layer;
an antiferromagnetic coupling layer adjacent to the first magnetic layer; and
a second magnetic layer adjacent to the antiferromagnetic coupling layer, the second magnetic layer antiferromagnetically coupled to the first magnetic layer,
wherein the antiferromagnetic coupling layer includes a layer containing an Ir—Re alloy and has an atom proportion of Re in the Ir—Re alloy of more than 0% and 12.5% or less.

[2] The stacked film according to [1],
wherein an atom proportion of Re in the Ir—Re alloy is 10% or less.

The stacked film according to [1], [3]
wherein an atom proportion of Re in the Ir—Re alloy is 4.5% or less.

[4] The stacked film according to [1],
wherein a layer containing Ir and Re in the antiferromagnetic coupling layer has a thickness of more than 0.2 nm and less than 1.0 nm.

[5] The stacked film according to [1],
wherein at least any of the first magnetic layer and the second magnetic layer includes a stacked layer of a Co layer and a Pt layer.

[6] The stacked film according to [1],
wherein the antiferromagnetic coupling layer includes a layer containing the Ir—Re alloy and a layer containing Pt or an alloy of Pt.

[7] The stacked film according to [1],
wherein the antiferromagnetic coupling layer includes a layer containing the Ir—Re alloy and a layer containing Ir.

[8] A magnetoresistive effect element including
a recording layer, a barrier layer, and a reference layer,
wherein the recording layer and the reference layer sandwich the barrier layer, and
wherein the reference layer includes the stacked film according to any one of the [1] to [7].

[9] A magnetoresistive effect element comprising
a conductive layer, a recording layer, a barrier layer, and a reference layer,
wherein the conductive layer includes the stacked film according to any one of [1] to [7], and
wherein the magnetoresistive effect element is configured such that a write current of a current flowing through the conductive layer causes a direction of magnetization in the recording layer to be reversed.

A semiconductor memory comprising the magnetoresistive effect element according to [8].

A logic LSI comprising the magnetoresistive effect element according to [8].

A semiconductor memory comprising the magnetoresistive effect element according to [9].

A logic LSI comprising the magnetoresistive effect element according to [9].

### Advantageous Effects of Invention

According to the present invention, the stacked film includes a first magnetic layer, an antiferromagnetic coupling layer adjacent to the first magnetic layer, and a second magnetic layer adjacent to the antiferromagnetic coupling layer and antiferromagnetically coupled to the first magnetic layer. The antiferromagnetic coupling layer includes a layer containing an Ir—Re alloy and has an atom proportion of Re in the Ir—Re alloy of more than 0% and 12.5% or less. Therefore, interlayer exchange coupling strength between the first magnetic layer and the second magnetic layer is strong. By using the stacked film in a magnetoresistive effect element, in a semiconductor memory including an STT-MRAM, an SOT-MRAM, and further an MRAM, in a conductive layer for SOT-MRAM, and in a logic LSI, spin devices, which have good thermal stability and high annealing tolerance enabling strong pinning that maintains perpendicular magnetic anisotropy even through an annealing process during fabrication, can be provided.

### BRIEF DESCRIPTION OF DRAWINGS

FIG. 1 is a diagram schematically illustrating a cross-sectional surface of a stacked film according to a first embodiment of the present invention.

FIG. 2A is a diagram schematically illustrating a cross-sectional surface of a stacked film according to a second embodiment of the present invention.

FIG. 2B is a diagram schematically illustrating a cross-sectional surface of a stacked film according to a third embodiment of the present invention.

FIG. 3A is a diagram schematically illustrating a cross-sectional surface of a stacked film according to a fourth embodiment of the present invention.

FIG. 3B is a diagram schematically illustrating a cross-sectional surface of a stacked film according to a fifth embodiment of the present invention.

FIG. 4 is a cross-sectional view illustrating an outline of a magnetoresistive effect element according to a sixth embodiment of the present invention.

FIG. 5 is a cross-sectional view illustrating in detail the magnetoresistive effect element according to the sixth embodiment of the present invention.

FIG. 6 is a cross-sectional view illustrating an outline of a magnetoresistive effect element according to a seventh embodiment of the present invention.

FIG. 7 is a cross-sectional view illustrating an outline of an SOT-MRAM according to an eighth embodiment of the present invention.

FIG. 8 is a cross-sectional view illustrating an outline of an SOT-MRAM according to a ninth embodiment of the present invention.

FIG. 9 is a cross-sectional view illustrating an outline of an SOT-MRAM according to a tenth embodiment of the present invention.

FIG. 10A is a diagram illustrating a structure of samples in Verification Experiment 1.

FIG. 10B is a diagram illustrating a structure of samples in Verification Experiment 2.

FIG. 10C is a diagram illustrating a structure of samples in Verification Experiment 3.

FIG. 11A is a drawing showing M-H curves of the sample having a film thickness t_{Ir} of Ir of 0.5 nm in Verification Experiment 1.

FIG. 11B shows M-H curves of the sample having a film thickness t_{IrRe} of Ir_{97.5}Re_{2.5} of 0.4 nm. FIG. 12 is a drawing showing the dependence of an interlayer interaction on a film thickness of Ir or IrRe concerning Verification Experiment 1 and Verification Experiment 2.

FIG. 13A is a drawing showing M-H curves of the sample of Verification Experiment 1 having a thickness of an interlayer coupling layer of 0.8 nm.

FIG. 13B is a drawing showing M-H curves of the sample of Verification Experiment 2 having a thickness of an interlayer coupling layer of 0.8 nm.

FIG. 13C is a drawing showing M-H curves of the sample of Verification Experiment 3 having a thickness of an interlayer coupling layer of 0.8 nm.

FIG. 14A is a drawing showing M-H curves of the sample of Verification Experiment 1 having a thickness of the interlayer coupling layer of 1.4 nm.

FIG. 14B is a drawing showing M-H curves of the sample of Verification Experiment 2 having a thickness of the interlayer coupling layer of 1.4 nm.

FIG. 14C is a drawing showing M-H curves of the sample of Verification Experiment 3 having a thickness of the interlayer coupling layer of 1.4 nm.

FIG. 15 is a diagram illustrating a structure of samples in Verification Experiment 4.

FIG. 16A shows an M-H measurement result after annealing a sample, in which the interlayer coupling layer is an Ir layer having a thickness of 0.5 nm and antiferromagnetic coupling occurs, in a vacuum at 300° C. for one hour.

FIG. 16B shows an M-H measurement result after annealing a sample, in which the interlayer coupling layer is an Ir_{95.5}Re_{4.5} layer having a thickness of 0.45 nm and antiferromagnetic coupling occurs, in a vacuum at 300° C. for one hour.

FIG. 16C shows an M-H measurement result after annealing a sample, in which the interlayer coupling layer is an Ir_{91.5}Re_{8.5} layer having a thickness of 0.5 nm and antiferromagnetic coupling occurs, in a vacuum at 300° C. for one hour.

FIG. 17A shows an M-H measurement result after annealing a sample, in which the interlayer coupling layer is an Ir layer having a thickness of 0.45 nm and antiferromagnetic coupling occurs, in a vacuum at 400° C. for one hour.

FIG. 17B shows an M-H measurement result after annealing a sample, in which the interlayer coupling layer is an Ir_{95.5}Re₄₅ layer having a thickness of 0.45 nm and antiferromagnetic coupling occurs, in a vacuum at 400° C. for one hour.

FIG. 17C shows an M-H measurement result after annealing a sample, in which the interlayer coupling layer is an Ir_{91.5}Re_{8.5} layer having a thickness of 0.5 nm and antiferromagnetic coupling occurs, in a vacuum at 400° C. for one hour.

FIG. 18A is a drawing showing the dependence of an interlayer exchange coupling |Jₑₓ| (mJ/m²) of a film thickness t_{IrRe} of IrRe on the film thickness t_{IrRe} of IrRe concerning the samples annealed in a vacuum at 300° C. for one hour in Verification Experiment 4.

FIG. 18B is a drawing showing the dependence of an interlayer exchange coupling |Jₑₓ| (mJ/m²) of a film thickness t_{IrRe} of IrRe on the film thickness t_{IrRe} of IrRe concerning the samples annealed in a vacuum at 400° C. for one hour in Verification Experiment 4.

FIG. 19A shows an M-H measurement result after annealing a sample having an interlayer coupling layer Ir_{97.5}Re_{2.5} with a film thickness t_{IrRe} of 0.4 nm at 300° C.

FIG. 19B shows an M-H measurement result after annealing a sample having an interlayer coupling layer Ir_{97.5}Re_{2.5} with a film thickness t_{IrRe} of 0.4 nm at 400° C.

FIG. 20A shows an M-H measurement result after annealing a sample having an interlayer coupling layer Ir_{98.5}Re_{1.5} with a film thickness t_{IrRe} of 0.35 nm at 300° C.

FIG. 20B shows an M-H measurement result after annealing a sample having an interlayer coupling layer Ir_{98.5}Re_{1.5} with a film thickness t_{IrRe} of 0.35 nm at 400° C.

FIG. 21 is a drawing showing the dependence of interlayer coupling strength on a Re composition.

FIG. 22A is a diagram illustrating a structure of samples in Verification Experiment 5.

FIG. 22B is a diagram illustrating a structure of samples in Verification Experiment 6.

FIG. 22C is a diagram illustrating a structure of samples in Verification Experiment 7.

FIG. 23A shows M-H curves of a sample having Pt layers with a thickness t_{Pt} of 0.4 nm and an interlayer coupling layer Ir_{95.5}Re_{4.5}.

FIG. 23B shows M-H curves of two samples having an interlayer coupling layer Ir_{95.5}Re_{4.5}.

FIG. 24A shows M-H curves of a sample having Pt layers with a thickness t_{Pt} of 0.6 nm and an interlayer coupling layer Ir_{97.5}Re_{2.5} layer.

FIG. 24B shows M-H curves of three samples having an interlayer coupling layer Ir_{97.5}Re_{2.5}.

FIG. 25A shows M-H curves of a sample having Pt layers with a thickness tri of 0.6 nm and an interlayer coupling layer Ir_{98.5}Re_{1.5} layer.

FIG. 25B shows M-H curves of three samples having an interlayer coupling layer Ir_{98.5}Re_{1.5}.

FIG. 26 shows the dependence of interlayer exchange coupling |Jₑₓ| on an Ru thickness as Comparative Experiment 1.

FIG. 27 shows the dependence of the interlayer exchange coupling |Jₑₓ| on an Ir thickness as Comparative Experiment 2.

FIG. 28A is a diagram illustrating a structure of the samples in Verification Experiment 8.

FIG. 28B is a diagram illustrating a structure of the samples in Verification Experiment 9.

FIG. 28C is a diagram illustrating a structure of the samples in Comparative Experiment 3.

FIG. 29A is the M-H curve for the sample with the Re/Ir/Re stacked layer with a film thickness t_{IrRe} of 0.5 nm in Verification Experiment 8, FIG. 29B is the M-H curve for the sample with the stacked layer Ir/Re/Ir with a film thickness t_{IrRe} of 0.5 nm in Verification Experiment 9, and FIG. 29C is the M-H curve for the sample with a film thickness t_{Ir} 0.55 nm of Ir in Comparative Experiment 3.

FIG. 30 a result plotting the interlayer exchange coupling |Jₑₓ| as a function of the film thickness t_{IrRe} the samples in Verification Experiments 8 and 9 and the film thickness t_{Ir} of Ir in Sample 3 in Comparative Experiment 3.

FIG. 31 is a diagram illustrating a semiconductor memory as an integrated circuit according to an eleventh embodiment of the present invention.

FIG. 32 is a diagram schematically illustrating a logic LSI as an integrated circuit according to a twelfth embodiment of the present invention.

### DESCRIPTION OF EMBODIMENTS

Some embodiments of the present invention will be described in detail with reference to the drawings below. Those matters described in the embodiments of the present invention can be appropriately modified in design without departing from the scope of the present invention.

### First Embodiment

FIG. 1 is a diagram schematically illustrating a cross-sectional surface of a stacked film according to a first embodiment of the present invention. A stacked film 10 according to the first embodiment of the present invention includes a first magnetic layer 11, an antiferromagnetic coupling layer 12 adjacent to the first magnetic layer 11, and a second magnetic layer 13 adjacent to the antiferromagnetic coupling layer 12. The second magnetic layer 13 is antiferromagnetically coupled to the first magnetic layer 11. That is, the stacked film 10 is configured to stack the first magnetic layer 11, the antiferromagnetic coupling layer 12, and the second magnetic layer 13 in this order. The antiferromagnetic coupling layer 12 includes a layer (referred to as an “interlayer coupling layer”) 12a made of an Ir—Re alloy. In the first embodiment of the present invention, the antiferromagnetic coupling layer 12 is constituted of the interlayer coupling layer 12a. The interlayer coupling layer 12a has a first surface and a second surface and has the first surface on an opposite side in an up and down direction from the second surface. The first surface (lower surface in FIG. 1) of the interlayer coupling layer 12a is in contact with the first magnetic layer 11, and the second surface (upper surface in FIG. 1) of the interlayer coupling layer 12a is in contact with the second magnetic layer 13.

The first magnetic layer 11 and the second magnetic layer 13 are ferromagnetic layers with the direction of magnetization facing in a film surface perpendicular direction. The first magnetic layer 11 and the second magnetic layer 13 include layers made of ferromagnetic materials containing one or a plurality of ferromagnetic transition metal elements. The ferromagnetic materials contain, for example, at least any of Co, Fe, Ni, and the like. The first magnetic layer 11 and the second magnetic layer 13 may include layers made of non-magnetic elements in addition to the layers made of ferromagnetic materials, and the non-magnetic elements include W, Ta, Hf, Zr, Nb, Mo, Ti, V, Cr, Si, Al, B, Pd, and Pt. The first magnetic layer 11 may have the same configuration as the second magnetic layer 13 or may have a different configuration.

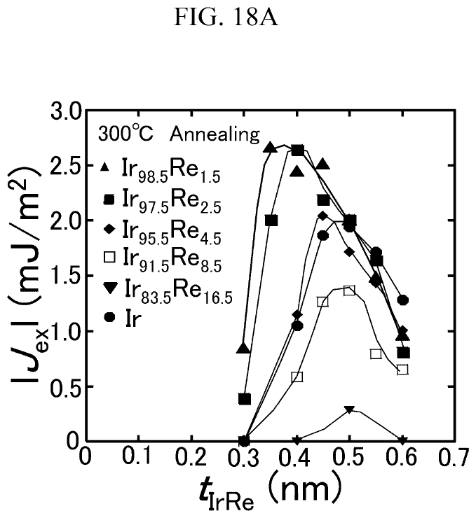

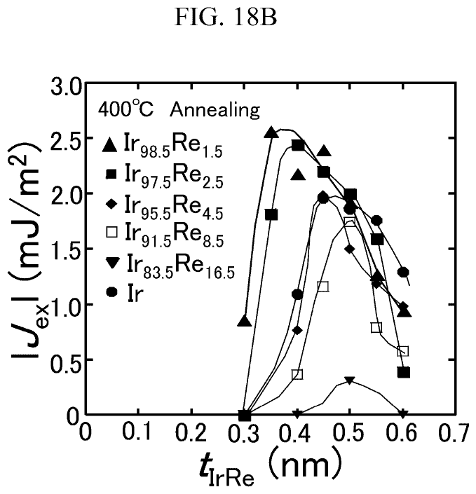

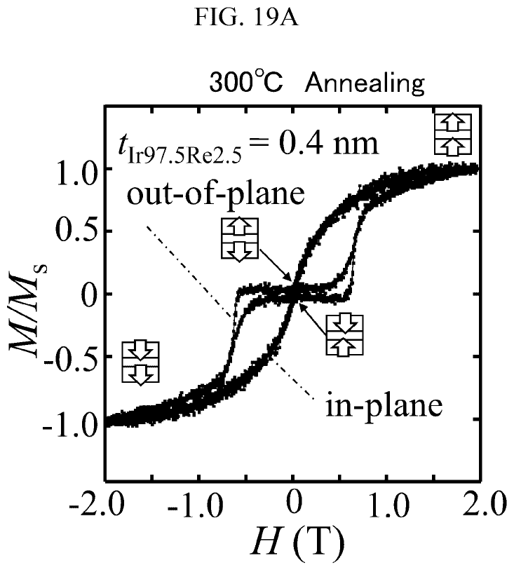

The first magnetic layer 11 and the second magnetic layer 13 are antiferromagnetically coupled via the interlayer coupling layer 12a. As the thickness of a non-magnetic layer (also referred to as an “interlayer coupling non-magnetic layer”) constituting the interlayer coupling layer 12a increases, an exchange coupling strength between the first magnetic layer 11 and the second magnetic layer 13 increases or decreases. For the exchange coupling strength, a strength (peak value), which increases as the thickness of the interlayer coupling layer 12a increases, gradually decreases. As the thickness of the interlayer coupling layer 12a is thickened from the smaller, the thickness at which the exchange coupling strength reaches a first peak becomes a value shorter than about 0.5 nm (see FIGS. 18A and 18B).

In the interlayer coupling layer 12a, an atom proportion of Re in the Ir—Re alloy is more than 0% and about 12.5% or less. That is, when the Ir—Re alloy is expressed by a chemical formula of IrₓRe_{y}, x and y satisfy x+y=100, and 0<y≤12.5

The atom proportion of Re in the Ir—Re alloy is preferably 10% or less. That is, it is preferable that y satisfies 0<y≤10. This is because the exchange coupling strength between the layers is about 1 mJ/m² or more.

The atom proportion of Re in the Ir—Re alloy is more preferably 4.5% or less. That is, it is more preferable that y satisfies 0<y≤4.5. This is because the exchange coupling strength between the layers becomes a value higher than about a value of 2 mJ/m² or more.

The atom proportion of Re in the Ir—Re alloy is further preferably 2.5% or less. That is, it is preferable that y satisfies 0<y≤2.5. This is because the exchange coupling strength between the layers is around a value of about 2.5 mJ/m² or more.

By containing Re in the Ir—Re alloy in the interlayer coupling layer 12a, for example, containing Re in 0.1% or more, more preferably 0.2% or more, and further preferably 0.5% or more, the interlayer coupling strength increases compared with a case without containing Re. Since the interlayer exchange coupling strength reaches a maximum value in a region where the interlayer coupling layer 12a is thin, interaction between the first magnetic layer 11 and the second magnetic layer 13 becomes strong (see FIGS. 18A and 18B, for example).

The layer (interlayer coupling layer 12a) containing the Ir—Re alloy has a thickness of more than 0.2 nm, more preferably more than 0.3 nm. The layer (interlayer coupling layer 12a) containing the Ir—Re alloy has a thickness of less than 1.0 nm, more preferably 0.6 nm or less. In the first embodiment, the layer containing Ir and Re in the antiferromagnetic coupling layer 12 is constituted of the interlayer coupling layer 12a.

In the first embodiment of the present invention, by including the layer (interlayer coupling layer 12a) made of an alloy of Ir and Re in the antiferromagnetic coupling layer 12, the exchange coupling between the first magnetic layer 11 and the second magnetic layer 13 enhances, the perpendicular magnetic anisotropy increases, so the thermal stability goes sufficiently well. In addition, the stacked film 10 has annealing tolerance at 300° C. to 400° C.

### Second Embodiment

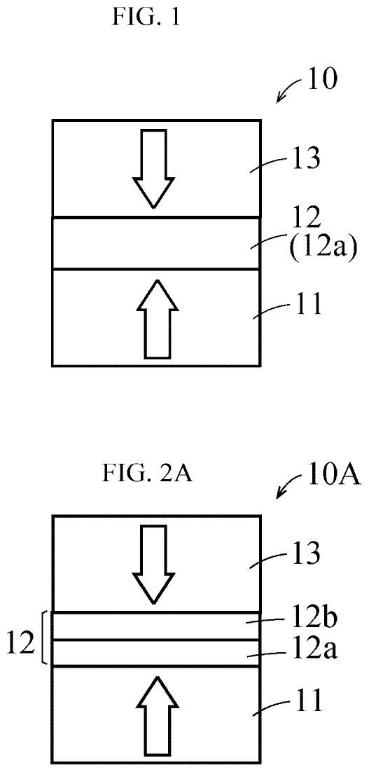

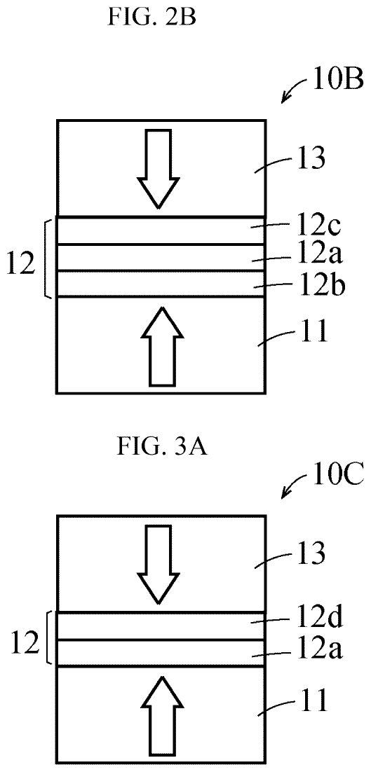

FIG. 2A is a diagram schematically illustrating a cross-sectional surface of a stacked film according to a second embodiment of the present invention. A stacked film 10A according to the second embodiment of the present invention includes a first magnetic layer 11, an antiferromagnetic coupling layer 12 adjacent to the first magnetic layer 11, and a second magnetic layer 13 adjacent to the antiferromagnetic coupling layer 12. The second magnetic layer 13 is antiferromagnetically coupled to the first magnetic layer 11. That is, the stacked film 10A is configured to stack the first magnetic layer 11, the antiferromagnetic coupling layer 12, and the second magnetic layer 13 in this order.

In the second embodiment of the present invention, the antiferromagnetic coupling layer 12 is constituted of a layer (interlayer coupling layer) 12a made of an Ir—Re alloy and a non-magnetic layer 12b. The layer 12a made of an Ir—Re alloy has a composition of the Ir—Re alloy similar to that of the first embodiment of the present invention. The non-magnetic layer 12b is made of a metal or an alloy containing Pt. Examples of the alloy containing Pt include, for example, Pt—Pd. The first magnetic layer 11 is similar to the first magnetic layer 11 in the first embodiment of the present invention, and the second magnetic layer 13 is similar to the second magnetic layer 13 in the first embodiment of the present invention.

In the second embodiment of the present invention, the antiferromagnetic coupling layer 12 is constituted of the interlayer coupling layer 12a and the non-magnetic layer 12b. The interlayer coupling layer 12a has a first surface and a second surface and has the first surface on an opposite side from the second surface. The first surface (lower surface in a form illustrated in FIG. 2A) of the interlayer coupling layer 12a is in contact with the first magnetic layer 11, and the second surface (upper surface in the form illustrated in FIG. 2A) of the interlayer coupling layer 12a is in contact with the non-magnetic layer 12b. The antiferromagnetic coupling layer 12 includes one layer each of the interlayer coupling layer 12a and the non-magnetic layer 12b. Here, different in the up and down direction of the antiferromagnetic coupling layer 12 from the form illustrated in FIG. 2A, the interlayer coupling layer 12a may be in contact with the second magnetic layer 13, and the non-magnetic layer 12b may be in contact with the first magnetic layer 11. That is, the first surface (lower surface) of the interlayer coupling layer 12a may be in contact with the non-magnetic layer 12b, and the second surface (upper surface) of the interlayer coupling layer 12a may be in contact with the second magnetic layer 13. The interlayer coupling layer 12a has a thickness similar to that of the first embodiment.

In the second embodiment of the present invention, the antiferromagnetic coupling layer 12 is configured to include the interlayer coupling layer 12a and the non-magnetic layer 12b. Therefore, when a material having a large spin Hall effect, such as Pt or Pt—Pd, is used for the non-magnetic layer 12b, spin torque increases compared with a case without having the non-magnetic layer 12b, and the magnetization of the first magnetic layer 11 and the second magnetic layer 13 is efficiently reversed. The stacked film 10A according to the second embodiment of the present invention can also be employed as a conductive layer of an SOT-MRAM (wiring for SOT-MRAM).

In the second embodiment of the present invention, by including the layer (interlayer coupling layer 12a) made of an alloy of Ir and Re in the antiferromagnetic coupling layer 12, the perpendicular magnetic anisotropy increases, so the thermal stability goes sufficiently well. In addition, the stacked film 10A has annealing tolerance at 300° C. to 400° C.

### Third Embodiment

FIG. 2B is a diagram schematically illustrating a cross-sectional surface of a stacked film according to a third embodiment of the present invention. A stacked film 10B according to the third embodiment of the present invention includes a first magnetic layer 11, an antiferromagnetic coupling layer 12 adjacent to the first magnetic layer 11, and a second magnetic layer 13 adjacent to the antiferromagnetic coupling layer 12. The second magnetic layer 13 is antiferromagnetically coupled to the first magnetic layer 11. That is, the stacked film 10B is configured to stack the first magnetic layer 11, the antiferromagnetic coupling layer 12, and the second magnetic layer 13 in this order.

In the third embodiment of the present invention, the antiferromagnetic coupling layer 12 is constituted of a layer (interlayer coupling layer) 12a made of an Ir—Re alloy, a first non-magnetic layer 12b, and a second non-magnetic layer 12c. The first non-magnetic layer 12b and the second non-magnetic layer 12c sandwich the interlayer coupling layer 12a. The interlayer coupling layer 12a has a composition of the Ir—Re alloy similar to that of the first embodiment of the present invention. The first non-magnetic layer 12b is made of a metal or an alloy containing Pt. The second non-magnetic layer 12c is made of a metal or an alloy containing Pt. Examples of the alloy containing Pt include, for example, Pt—Pd. The first non-magnetic layer 12b may have the same configuration as the second non-magnetic layer 12c or may have a different configuration. The first magnetic layer 11 is similar to the first magnetic layer 11 in the first embodiment of the present invention, and the second magnetic layer 13 is similar to the second magnetic layer 13 in the first embodiment of the present invention. The interlayer coupling layer 12a has a thickness similar to that of the first embodiment.

In the third embodiment of the present invention, the antiferromagnetic coupling layer 12 includes the first non-magnetic layer 12b and the second non-magnetic layer 12c. Therefore, the spin torque increases compared with a case without having the first non-magnetic layer 12b or the second non-magnetic layer 12c, and the magnetization of the first magnetic layer 11 and the second magnetic layer 13 is efficiently reversed. The stacked film 10B according to the third embodiment can be employed as a conductive layer of a SOT-MRAM (wiring for SOT-MRAM).

In the third embodiment of the present invention, by including the layer (interlayer coupling layer 12a) made of an alloy of Ir and Re in the antiferromagnetic coupling layer 12, the perpendicular magnetic anisotropy increases, so the thermal stability goes sufficiently well. In addition, the stacked film 10B has annealing tolerance at 300° C. to 400° C.

### Fourth Embodiment

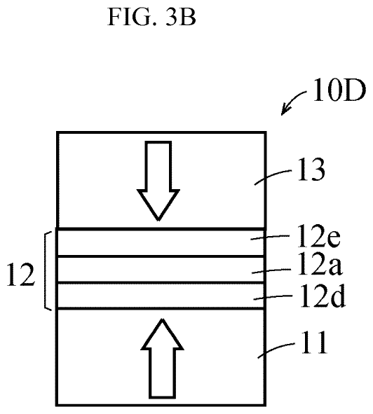

FIG. 3A is a diagram schematically illustrating a cross-sectional surface of a stacked film according to a fourth embodiment of the present invention. A stacked film 10C according to the fourth embodiment of the present invention includes a first magnetic layer 11, an antiferromagnetic coupling layer 12 adjacent to the first magnetic layer 11, and a second magnetic layer 13 adjacent to the antiferromagnetic coupling layer 12. The second magnetic layer 13 is antiferromagnetically coupled to the first magnetic layer 11. That is, the stacked film 10C is configured to stack the first magnetic layer 11, the antiferromagnetic coupling layer 12, and the second magnetic layer 13 in this order.

In the fourth embodiment of the present invention, the antiferromagnetic coupling layer 12 is constituted of a layer (interlayer coupling layer) 12a made of an Ir—Re alloy and a non-magnetic layer 12d. The non-magnetic layer 12d is a layer that does not contain Re but contains Ir(Ir layer). The thickness of the non-magnetic layer (Ir layer) 12d and the composition of Re in the layer 12a containing an Ir—Re alloy are adjusted such that the composition of Ir and Re when the layer 12a containing an Ir—Re alloy and the non-magnetic layer 12d are viewed as one layer is consistent with the preferred composition in the first embodiment of the present invention. Here, determining the thickness of the non-magnetic layer (Ir layer) 12d means nothing other than adjusting the thickness of the layer 12a containing an Ir—Re alloy. The first magnetic layer 11 is similar to the first magnetic layer 11 in the first embodiment of the present invention, and the second magnetic layer 13 is similar to the second magnetic layer 13 in the first embodiment of the present invention. In the fourth embodiment, the layer containing Ir and Re in the antiferromagnetic coupling layer 12 is constituted of the layer 12a containing an Ir—Re alloy and the non-magnetic layer 12d.

In the fourth embodiment of the present invention, the antiferromagnetic coupling layer 12 is constituted of the interlayer coupling layer 12a and the non-magnetic layer 12d. The interlayer coupling layer 12a has a first surface and a second surface and has the first surface on an opposite side from the second surface. The first surface (lower surface in a form illustrated in FIG. 3A) of the interlayer coupling layer 12a is in contact with the first magnetic layer 11, and the second surface (upper surface in the form illustrated in FIG. 3A) of the interlayer coupling layer 12a is in contact with the non-magnetic layer 12d. The antiferromagnetic coupling layer 12 includes one layer each of the interlayer coupling layer 12a and the non-magnetic layer 12d. Here, different in the up and down direction of the antiferromagnetic coupling layer 12 from the form illustrated in FIG. 3A, the interlayer coupling layer 12a may be in contact with the second magnetic layer 13, and the non-magnetic layer 12d may be in contact with the first magnetic layer 11. That is, the first surface (lower surface) of the interlayer coupling layer 12a may be in contact with the non-magnetic layer 12d, and the second surface (upper surface) of the interlayer coupling layer 12a may be in contact with the second magnetic layer 13.

In the fourth embodiment of the present invention, the antiferromagnetic coupling layer 12 includes the interlayer coupling layer 12a and the non-magnetic layer 12d. The interlayer coupling layer 12a has a thickness similar to that of the first embodiment. The antiferromagnetic coupling layer 12 is constituted of the layer (interlayer coupling layer) 12a made of an Ir—Re alloy and the non-magnetic layer (Ir layer) 12d. The thickness of the layer (Ir layer) 12d containing Ir and the composition of Re in the layer 12a containing an Ir—Re alloy are adjusted such that the composition of Ir and Re when the layer 12a containing an Ir—Re alloy and the non-magnetic layer (Ir layer) 12d are viewed as one layer is consistent with the preferred composition in the first embodiment of the present invention. Then, the thickness of the antiferromagnetic coupling layer 12 (that is, the sum of the thickness of the interlayer coupling layer 12a and the thickness of the non-magnetic layer 12d) in the fourth embodiment is the same as the thickness of the interlayer coupling layer 12a in the antiferromagnetic coupling layer 12 in the first embodiment. In the fourth embodiment, the layer containing Ir and Re in the antiferromagnetic coupling layer 12 is constituted of the layer 12a containing an Ir—Re alloy and the non-magnetic layer 12d. When these conditions are met, similarly to the first embodiment, the perpendicular magnetic anisotropy increases, so the thermal stability goes sufficiently well. In addition, the stacked film 10C has annealing tolerance at 300° C. to 400° C. The stacked film 10C can be employed as a reference layer of MTJ.

### Fifth Embodiment

FIG. 3B is a diagram schematically illustrating a cross-sectional surface of a stacked film according to a fifth embodiment of the present invention. A stacked film 10D according to the fifth embodiment of the present invention includes a first magnetic layer 11, an antiferromagnetic coupling layer 12 adjacent to the first magnetic layer 11, and a second magnetic layer 13 adjacent to the antiferromagnetic coupling layer 12. The second magnetic layer 13 is antiferromagnetically coupled to the first magnetic layer 11. That is, the stacked film 10D is configured to stack the first magnetic layer 11, the antiferromagnetic coupling layer 12, and the second magnetic layer 13 in this order.

In the fifth embodiment of the present invention, the antiferromagnetic coupling layer 12 is constituted of a layer (interlayer coupling layer) 12a made of an Ir—Re alloy, a first non-magnetic layer 12d, and a second non-magnetic layer 12e. The interlayer coupling layer 12a has a thickness similar to that of the first embodiment. The first non-magnetic layer 12d and the second non-magnetic layer 12e sandwich the interlayer coupling layer 12a. Each of the first non-magnetic layer 12d and the second non-magnetic layer 12e is a layer that does not contain Re but contains Ir(Ir layer). Here, the thicknesses of the first non-magnetic layer 12d and the second non-magnetic layer 12e and the composition of Re in the layer 12a containing an Ir—Re alloy are adjusted such that the composition of Ir and Re when the layer 12a containing an Ir—Re alloy, the first non-magnetic layer 12d, and the second non-magnetic layer 12e are viewed as one layer is consistent with the preferred composition in the first embodiment of the present invention. The first non-magnetic layer 12d may have the same configuration as the second non-magnetic layer 12e or may have a different configuration. The first magnetic layer 11 is similar to the first magnetic layer 11 in the first embodiment of the present invention, and the second magnetic layer 13 is similar to the second magnetic layer 13 in the first embodiment of the present invention. In the fifth embodiment, the layer containing Ir and Re in the antiferromagnetic coupling layer 12 is constituted of the first non-magnetic layer 12d, the layer 12a containing an Ir—Re alloy, and the second non-magnetic layer 12e.

In the fifth embodiment of the present invention, the antiferromagnetic coupling layer 12 includes the interlayer coupling layer 12a, the first non-magnetic layer 12d, and the second non-magnetic layer 12e. The thicknesses of the first non-magnetic layer 12d and the second non-magnetic layer 12e and the composition of Re in the layer 12a containing an Ir—Re alloy are adjusted such that the composition of Ir and Re when the layer 12a containing an Ir—Re alloy, the first non-magnetic layer 12d, and the second non-magnetic layer 12e are viewed as one layer is consistent with the preferred composition in the first embodiment of the present invention. Then, the thickness of the antiferromagnetic coupling layer 12 (that is, the sum of the thickness of the interlayer coupling layer 12a, the thickness of the first non-magnetic layer 12d, and the thickness of the second non-magnetic layer 12e) in the fifth embodiment is the same as the thickness of the interlayer coupling layer 12a in the antiferromagnetic coupling layer 12 in the first embodiment. In the fifth embodiment, the layer containing Ir and Re in the antiferromagnetic coupling layer 12 is constituted of the first non-magnetic layer 12d, the layer 12a containing an Ir—Re alloy, and the second non-magnetic layer 12e. When these conditions are met, similarly to the first embodiment, the perpendicular magnetic anisotropy increases, so the thermal stability goes sufficiently well. In addition, the stacked film 10D has annealing tolerance at 300° C. to 400° C. The stacked film 10D can be employed as a reference layer of MTJ. The thickness of the first non-magnetic layer 12d may be equal to or different from the thickness of the second non-magnetic layer 12e.

### Sixth Embodiment

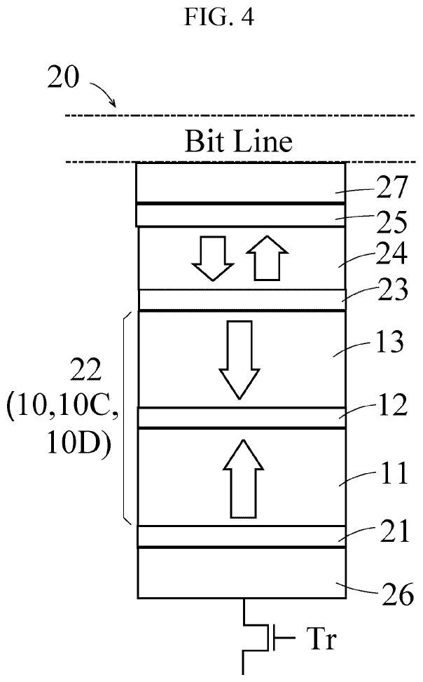

FIG. 4 is a cross-sectional view illustrating an outline of a magnetoresistive effect element according to a sixth embodiment of the present invention. In a magnetoresistive effect element 20 according to the sixth embodiment of the present invention, the stacked film 10 illustrated in FIG. 1 is applied as a part of a reference layer 22. That is, the reference layer 22 has a ferromagnetic pinned layer (synthetic anti-ferromagnetic layer: SAF layer). The magnetoresistive effect element 20 illustrated in FIG. 4 has a bottom pin structure. That is, the magnetoresistive effect element 20 includes the reference layer 22, a tunnel barrier layer 23, and a recording layer 24 from the lower side in this order, and a stacked layer of the reference layer 22, the tunnel barrier layer 23, and the recording layer 24 is disposed between a seed layer 21 and a cap layer 25.

The reference layer 22 includes any of the above-described respective stacked films 10 (for example, the stacked film 10 illustrated in FIG. 1, the stacked film 10C illustrated in FIG. 3A, and the stacked film 10D illustrated in FIG. 3B) and is configured to stack at least the first magnetic layer 11, the antiferromagnetic coupling layer 12, and the second magnetic layer 13 in this order. The first magnetic layer 11 and the second magnetic layer 13 are antiferromagnetically coupled. The tunnel barrier layer 23 is disposed on the second magnetic layer 13 and under the recording layer 24. That is, the tunnel barrier layer 23 is disposed between the second magnetic layer 13 and the recording layer 24. The recording layer 24 is configured to include a magnetic layer having perpendicular magnetic anisotropy. A lower electrode 26 is connected to the seed layer 21, the lower electrode 26 is connected to a selective transistor Tr, and an upper electrode 27 is connected to the cap layer 25. The upper electrode 27 is connected to a bit line.

The magnetoresistive effect element 20 constitutes an STT-MRAM. By flowing current between the seed layer 21 and the cap layer 25 in a state where the selective transistor Tris ON, the recording layer 24 is rewritten or read. At that time, in the sixth embodiment of the present invention, since the reference layer 22 includes the stacked film 10, 10C, or 10D, the perpendicular magnetic anisotropy of the first magnetic layer 11 and the second magnetic layer 13 increases, so the thermal stability goes sufficiently well. As a result, the perpendicular magnetization of the first magnetic layer 11 and the second magnetic layer 13 can be more fixed and pinned.

In the sixth embodiment of the present invention, the reference layer 22 is configured to stack the first magnetic layer 11, the antiferromagnetic coupling layer 12, and the second magnetic layer 13 in this order. The first magnetic layer 11 and the second magnetic layer 13 are antiferromagnetically coupled. Thus, the reference layer 22 has the ferromagnetic pinned layer (SAF layer), and the perpendicular magnetic anisotropy of the first magnetic layer 11 and the second magnetic layer 13 is large. Therefore, the thermal stability goes sufficiently well, and even when the element size is miniaturized, write errors are suppressed.

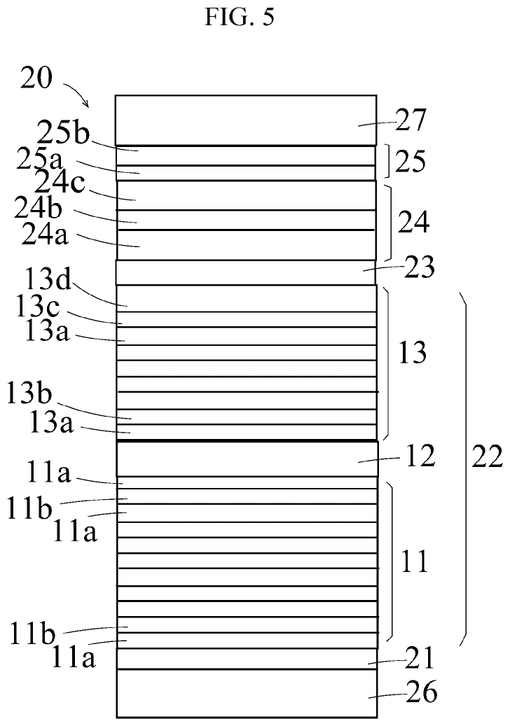

FIG. 5 is a cross-sectional view illustrating in detail the magnetoresistive effect element according to the sixth embodiment of the present invention. In the magnetoresistive effect element 20 according to the sixth embodiment of the present invention, the first magnetic layer 11 in the reference layer 22 includes a stacked layer of Co layers 11a and Pt layers 11b. The second magnetic layer 13 in the reference layer 22 includes a stacked layer of Co layers 13a and Pt layers 13b. The first magnetic layer 11 and the second magnetic layer 13 include Co/Pt multilayers. Both an upper layer and a lower layer included in the Co/Pt multilayer in the first magnetic layer 11 are the Co layers 11a. The uppermost Co layer 11a is connected to the antiferromagnetic coupling layer 12 (interlayer coupling layer 12a). The second magnetic layer 13 includes a layer 13c containing at least any of Ta, W, Mo, and the like and a CoFeB layer 13d, in addition to the Co/Pt multilayer. Both an upper layer and a lower layer included in the Co/Pt multilayer in the second magnetic layer 13 are the Co layers 13a. The lowermost Co layer 13a is connected to the antiferromagnetic coupling layer 12 (interlayer coupling layer 12a). The uppermost Co layer 13a is connected to the layer 13c containing at least any of Ta, W, Mo, and the like. The layer 13c is connected to the CoFeB layer 13d, and the CoFeB layer 13d is joined to the tunnel barrier layer 23.

The recording layer 24 includes a CoFeB layer 24a and a layer 24b containing at least any of Ta, W, Mo, MgO, and the like and has a stack structure including CoFeB layer 24a/layer 24b containing at least any of Ta, W, Mo, MgO, and the like/CoFeB layer 24c. Here, a stack of CoFeB layer 24a/layer 24b containing at least any of Ta, W, Mo, MgO, and the like may be further stacked into multiple layers. Here, the CoFeB layer 13d and the CoFeB layer 24a are disposed in order to increase a magnetoresistive effect (MR). When the tunnel barrier layer 23 is an MgO layer, the CoFeB layer 13d and the CoFeB layer 24a positioned on or above and under the tunnel barrier layer 23 are preferably iron-rich. When the tunnel barrier layer 23 is an MgO layer, the CoFeB layer 13d is prone to perpendicular magnetization. The layer 13c is disposed in order to differentiate crystalline structures between an fcc structure of the Co/Pt multilayer and a bcc structure of the CoFeB layer 13d and the CoFeB layer 24a near the MgO layer. By providing the layer 13c on the Co/Pt multilayer, forming an amorphous layer of CoFeB on the layer 13c, providing MgO crystals, and providing an amorphous layer of CoFeB to anneal, the bcc structure of the CoFeB layer 13d and the CoFeB layer 24a near the MgO layer is formed. The cap layer 25 is constituted of an MgO layer 25a and a layer 25b containing at least any of Ru, Ta, W, and the like. Here, the cap layer 25 may only include the layer 25b containing at least any of Ru, Ta, W, and the like.

In the magnetoresistive effect element 20 illustrated in FIG. 5, since the first magnetic layer 11 and the second magnetic layer 13 in the reference layer 22 have the Co/Pt multilayers, the perpendicular magnetic anisotropy is strong.

### Seventh Embodiment

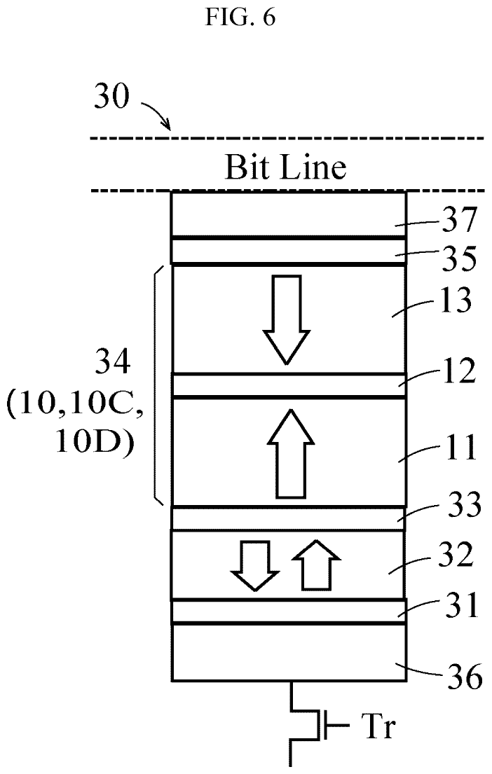

FIG. 6 is a cross-sectional view illustrating an outline of a magnetoresistive effect element according to a seventh embodiment of the present invention. In a magnetoresistive effect element 30 according to the seventh embodiment of the present invention, any of the above-described respective various stacked films 10 (for example, the stacked film 10 illustrated in FIG. 1, the stacked film 10C illustrated in FIG. 3A, and the stacked film 10D illustrated in FIG. 3B) is applied as a part of a reference layer 34 (pinned layer). That is, the reference layer 34 has a ferromagnetic pinned layer (SAF layer). The magnetoresistive effect element 30 illustrated in FIG. 6 has a top pin structure. That is, the magnetoresistive effect element 30 includes a recording layer 32, a tunnel barrier layer 33, and the reference layer 34 from the lower side in this order, and the recording layer 32, the tunnel barrier layer 33, and the reference layer 34 are disposed between a seed layer 31 and a cap layer 35.

The reference layer 34 includes the stacked film 10 illustrated in FIG. 1 and is configured to stack at least the first magnetic layer 11, the antiferromagnetic coupling layer 12, and the second magnetic layer 13 in this order. The tunnel barrier layer 33 is disposed on the recording layer 32 and under the first magnetic layer 11. The tunnel barrier layer 33 is disposed between the recording layer 32 and the first magnetic layer 11. The recording layer 32 is configured to include a magnetic layer having perpendicular magnetic anisotropy. A lower electrode 36 is connected to the seed layer 31, the lower electrode 36 is connected to a selective transistor Tr, and an upper electrode 37 is connected to the cap layer 35. The upper electrode 37 is connected to a bit line.

The magnetoresistive effect element 30 constitutes an STT-MRAM. By flowing current between the seed layer 31 and the cap layer 35 in a state where the selective transistor Tris ON, the recording layer 32 is rewritten or read. At that time, in the seventh embodiment of the present invention, since the reference layer 34 includes the stacked film 10, 10C, or 10D, the perpendicular magnetic anisotropy of the first magnetic layer 11 and the second magnetic layer 13 increases, so the thermal stability goes sufficiently well. As a result, the perpendicular magnetization of the first magnetic layer 11 and the second magnetic layer 13 can be more fixed and pinned.

In the seventh embodiment of the present invention, the reference layer 34 is configured to stack the first magnetic layer 11, the antiferromagnetic coupling layer 12, and the second magnetic layer 13 in this order. The first magnetic layer 11 and the second magnetic layer 13 are antiferromagnetically coupled. Thus, the reference layer 34 has the ferromagnetic pinned layer (SAF layer), and the perpendicular magnetic anisotropy of the first magnetic layer 11 and the second magnetic layer 13 is large. Therefore, the thermal stability goes sufficiently well, and even when the element size is miniaturized, write errors are suppressed.

### Eighth Embodiment

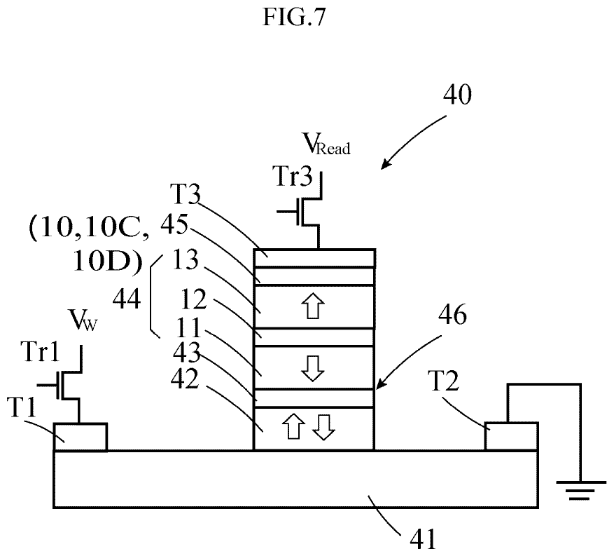

FIG. 7 is a cross-sectional view illustrating an outline of an SOT-MRAM according to an eighth embodiment of the present invention. An SOT-MRAM 40 according to the eighth embodiment of the present invention includes a conductive layer 41 and a magnetoresistive effect element 46. The magnetoresistive effect element 46 is disposed on the conductive layer 41 and includes a recording layer 42, a tunnel barrier layer 43, and a reference layer 44.

The reference layer 44 includes any of the above-described respective various stacked films 10 (for example, the stacked film 10 illustrated in FIG. 1, the stacked film 10C illustrated in FIG. 3A, and the stacked film 10D illustrated in FIG. 3B) and is configured to stack at least the first magnetic layer 11, the antiferromagnetic coupling layer 12, and the second magnetic layer 13 in this order. The first magnetic layer 11 is disposed between the tunnel barrier layer 43 and the antiferromagnetic coupling layer 12 (for example, the interlayer coupling layer 12a or the non-magnetic layer 12d). The second magnetic layer 13 is disposed between the antiferromagnetic coupling layer 12 (for example, the interlayer coupling layer 12a or the non-magnetic layer 12d or 12e) and a cap layer 45. The details of the antiferromagnetic coupling layer 12 are not illustrated in FIG. 7.

The recording layer 42 includes a layer that allows magnetization reversal and that has perpendicular magnetic anisotropy. The tunnel barrier layer 43 is constituted of MgO or the like and disposed between the recording layer 42 and the first magnetic layer 11.

The conductive layer 41 may include a stacked layer of a βW layer and a βTa layer or may include a Pt layer and a synthetic AF layer having a Co/Pt/Ir/Pt/Co stacked film. As detailed in a ninth embodiment and a tenth embodiment below, using the stacked film 10A of the second embodiment or the stacked film 10B of the third embodiment improves the perpendicular magnetic anisotropy more.

A first terminal T1 and a second terminal T2 are disposed on the conductive layer 41 or disposed to be electrically connected to the conductive layer 41. A first transistor Tr1 is connected to the first terminal T1, and grounded to the second terminal T2 by interposing a second transistor (not illustrated) as necessary. The cap layer 45 is disposed on the reference layer 44, a third terminal T3 is disposed on the cap layer 45, and a third transistor Tr3 is connected to the third terminal T3. The first terminal T1 is arranged on an opposite side from the second terminal T2 across the recording layer 42, the tunnel barrier layer 43, and the reference layer 44.

By applying a write voltage Vw to the first terminal T1 to flow current between the first terminal T1 and the second terminal T2 in a state where the first transistor Tr1 is ON, current that has been pinned and unevenly distributed is flowed through the conductive layer 41. Then, the magnetization of the recording layer 42 can be reversed by spin-orbit torque.

A read voltage V_{Read} is applied to the third terminal T3 in a state where the third transistor Tr3 is ON to flow current between the second terminal T2 and the third terminal T3. From the magnitude of the current, data of “0” or “1” corresponding to a parallel state or an antiparallel state of the magnetization in the recording layer 42 and the reference layer 44 can be read.

The SOT-MRAM 40 according to the eighth embodiment of the present invention includes the magnetoresistive effect element 30 according to the seventh embodiment of the present invention. That is, the reference layer 44 is configured to stack the first magnetic layer 11, the antiferromagnetic coupling layer 12, and the second magnetic layer 13 in this order. The first magnetic layer 11 and the second magnetic layer 13 are antiferromagnetically coupled. Thus, the reference layer 44 has a ferromagnetic pinned layer (SAF layer), and the perpendicular magnetic anisotropy of the first magnetic layer 11 and the second magnetic layer 13 is large. Therefore, the thermal stability goes sufficiently well. As a result, the perpendicular magnetization of the first magnetic layer 11 and the second magnetic layer 13 can be more fixed and pinned. This can reduce write errors even when the element is miniaturized. Thus, the SOT-MRAM 40 has three terminals including the first terminal T1, the second terminal T2, and the third terminal T3. The SOT-MRAM 40 is configured such that the direction of magnetization in the recording layer 42 is reversed by a write current flowing through the conductive layer 41.

### Ninth Embodiment

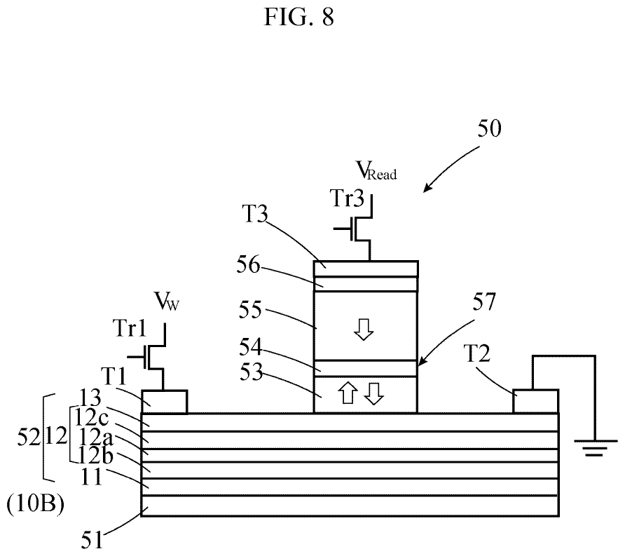

FIG. 8 is a cross-sectional view illustrating an outline of an SOT-MRAM according to the ninth embodiment of the present invention. An SOT-MRAM 50 according to the ninth embodiment of the present invention includes a conductive layer 52 including any of the above-described respective various stacked films 10 (for example, the stacked films 10A according to the second embodiment of the present invention and the stacked film 10B according to the third embodiment of the present invention) and a magnetoresistive effect element 57. The magnetoresistive effect element 57 is disposed on the conductive layer 52 and configured to stack a recording layer 53, a tunnel barrier layer 54, and a reference layer 55 in this order.

The conductive layer 52 includes a first magnetic layer 11, an antiferromagnetic coupling layer 12, and a second magnetic layer 13. The antiferromagnetic coupling layer 12 is disposed between the first magnetic layer 11 and the second magnetic layer 13. The antiferromagnetic coupling layer 12 illustrated in FIG. 8 includes an Ir—Re alloy layer (interlayer coupling layer 12a), a first non-magnetic layer 12b adjacent to a first surface (lower surface in the drawing) of the Ir—Re alloy layer (interlayer coupling layer 12a), and a second non-magnetic layer 12c adjacent to a second surface (upper surface in the drawing) of the Ir—Re alloy layer (interlayer coupling layer 12a). The first non-magnetic layer 12b and the second non-magnetic layer 12c include a Pt layer or a Pt—Pd alloy layer. The conductive layer 52 is disposed on a seed layer 51.

The conductive layer 52 includes a stack structure of first magnetic layer 11/first non-magnetic layer 12b/interlayer coupling layer 12a/second non-magnetic layer 12c/second magnetic layer 13. A spin Hall angle increases, and the first magnetic layer 11 is antiferromagnetically coupled to the second magnetic layer 13, thereby allowing a reduction in stray magnetic field.

The recording layer 53 includes a layer that allows magnetization reversal and has perpendicular magnetic anisotropy. The tunnel barrier layer 54 is sandwiched between the recording layer 53 and the reference layer 55. The reference layer 55 includes a ferromagnetic layer having perpendicular magnetic anisotropy with magnetization fixed.

A first terminal T1 and a second terminal T2 are disposed on the conductive layer 52 or disposed to be electrically connected to the conductive layer 52. A first transistor Tr1 is connected to the first terminal T1, and grounded to the second terminal T2 by interposing a second transistor (not illustrated) as necessary. A cap layer 56 is disposed on the reference layer 55, a third terminal T3 is disposed on the cap layer 56, and a third transistor Tr3 is connected to the third terminal T3. The first terminal T1 is arranged on an opposite side from the second terminal T2 across the recording layer 53, the tunnel barrier layer 54, and the reference layer 55.

By applying the write voltage Vw to the first terminal T1 to flow current between the first terminal T1 and the second terminal T2 in a state where the first transistor Tr1 is ON, current that has been pinned and unevenly distributed is flowed through the conductive layer 52. Then, the magnetization of the recording layer 53 can be reversed by spin-orbit torque.

The read voltage V_{Read} is applied to the third terminal T3 in a state where the third transistor Tr3 is ON to flow current between the second terminal T2 and the third terminal T3. From the magnitude of the current, data of “0” or “1” corresponding to a parallel state or an antiparallel state of the magnetization in the recording layer 53 and the reference layer 55 can be read.

In the SOT-MRAM 50 according to the ninth embodiment of the present invention, the conductive layer 52 includes the stacked film 10B according to the third embodiment of the present invention. Therefore, in the conductive layer 52, the perpendicular magnetic anisotropy of the first magnetic layer 11 and the second magnetic layer 13 increases, so the thermal stability goes sufficiently well. The spin Hall angle increases, and the first magnetic layer 11 is antiferromagnetically coupled to the second magnetic layer 13, thereby allowing a reduction in stray magnetic field. Thus, the SOT-MRAM 50 has three terminals including the first terminal T1, the second terminal T2, and the third terminal T3. The SOT-MRAM 50 is configured such that the direction of magnetization in the recording layer 53 is reversed by a write current flowing through the conductive layer 52.

In the ninth embodiment of the present invention, the conductive layer 52 may have the stacked film 10A according to the second embodiment of the present invention. That is, the conductive layer 52 may have a stack structure of first magnetic layer 11/non-magnetic layer 12b/Ir—Re alloy layer (interlayer coupling layer) 12a/second magnetic layer 13. The spin Hall angle increases, and the first magnetic layer 11 is antiferromagnetically coupled to the second magnetic layer 13, thereby allowing a reduction in stray magnetic field. The conductive layer 52 may have a stack structure of first magnetic layer 11/Ir—Re alloy layer (interlayer coupling layer) 12a/non-magnetic layer 12b/second magnetic layer 13. Even in this case, the spin Hall angle increases, and the first magnetic layer 11 is antiferromagnetically coupled to the second magnetic layer 13, thereby allowing a reduction in stray magnetic field.

### Tenth Embodiment

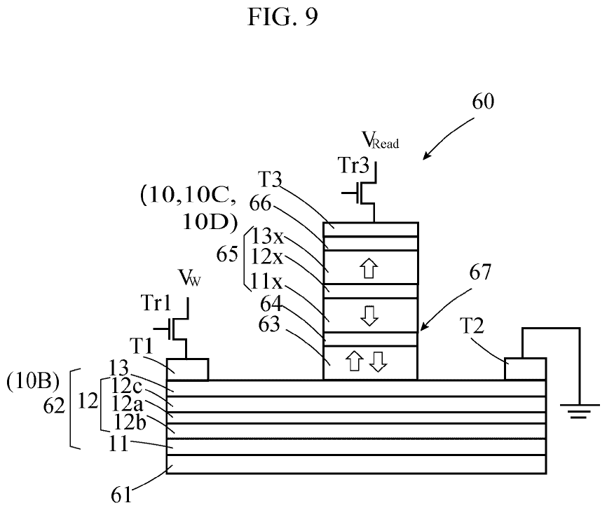

FIG. 9 is a cross-sectional view illustrating an outline of an SOT-MRAM according to the tenth embodiment of the present invention. An SOT-MRAM 60 according to the tenth embodiment of the present invention includes a conductive layer 62 including the stacked film 10B according to the third embodiment of the present invention and a magnetoresistive effect element 67. The magnetoresistive effect element 67 is disposed on the conductive layer 62 and configured to stack a recording layer 63, a tunnel barrier layer 64, and a reference layer 65 in this order. The reference layer 65 includes any of the above-described respective various stacked films 10 (for example, the stacked film 10 according to the first embodiment of the present invention, the stacked film 10C illustrated in FIG. 3A, and the stacked film 10D illustrated in FIG. 3B).

The conductive layer 62 includes a first magnetic layer 11, an antiferromagnetic coupling layer 12, and a second magnetic layer 13. The antiferromagnetic coupling layer 12 is disposed between the first magnetic layer 11 and the second magnetic layer 13. The antiferromagnetic coupling layer 12 illustrated in FIG. 9 includes an Ir—Re alloy layer (interlayer coupling layer 12a), a first non-magnetic layer 12b adjacent to a first surface (lower surface in the drawing) of the Ir—Re alloy layer (interlayer coupling layer 12a), and a second non-magnetic layer 12c adjacent to a second surface (upper surface in the drawing) of the Ir—Re alloy layer (interlayer coupling layer 12a). The first non-magnetic layer 12b and the second non-magnetic layer 12c include a Pt layer or a Pt—Pd alloy layer. The conductive layer 62 is disposed on a seed layer 61.

The conductive layer 62 includes a stack structure of first magnetic layer 11/first non-magnetic layer 12b/interlayer coupling layer 12a/second non-magnetic layer 12c/second magnetic layer 13. The spin Hall angle increases, and the first magnetic layer 11 is antiferromagnetically coupled to the second magnetic layer 13, thereby allowing a reduction in stray magnetic field.

The reference layer 65 includes any of the above-described respective various stacked films 10 (for example, the stacked film 10 illustrated in FIG. 1, the stacked film 10C illustrated in FIG. 3A, and the stacked film 10D illustrated in FIG. 3B) and is configured to stack at least a first magnetic layer 11x, an antiferromagnetic coupling layer 12x, and a second magnetic layer 13x in this order. The first magnetic layer 11x and the second magnetic layer 13x are antiferromagnetically coupled. Thus, the reference layer 65 has a ferromagnetic pinned layer (SAF layer), and the perpendicular magnetic anisotropy of the first magnetic layer 11x and the second magnetic layer 13x is high. Accordingly, the thermal stability goes sufficiently well, and write errors are suppressed. The first magnetic layer 11x is disposed between the tunnel barrier layer 64 and the antiferromagnetic coupling layer 12x. The second magnetic layer 13x is disposed between the antiferromagnetic coupling layer 12x and a cap layer 66. The recording layer 63 is configured to include a magnetic layer that allows magnetization reversal and that has perpendicular magnetic anisotropy. The details of the antiferromagnetic coupling layer 12x are not illustrated in FIG. 9.

A first terminal T1 and a second terminal T2 are disposed on the conductive layer 62 or disposed to be electrically connected to the conductive layer 62. A first transistor Tr1 is connected to the first terminal T1, and grounded to the second terminal T2 by interposing a second transistor (not illustrated) as necessary. The cap layer 66 is disposed on the reference layer 65, a third terminal T3 is disposed on the cap layer 66, and a third transistor Tr3 is connected to the third terminal T3. The first terminal T1 is arranged on an opposite side from the second terminal T2 across the recording layer 63, the tunnel barrier layer 64, and the reference layer 65.

By applying the write voltage Vw to the first terminal T1 to flow current between the first terminal T1 and the second terminal T2 in a state where the first transistor Tr1 is ON, current that has been pinned and unevenly distributed is flowed through the conductive layer 62. Then, the magnetization of the recording layer 63 can be reversed by spin-orbit torque.

The read voltage V_{Read} is applied to the third terminal T3 in a state where the third transistor Tr3 is ON to flow current between the second terminal T2 and the third terminal T3. From the magnitude of the current, data of “0” or “1” corresponding to a parallel state or an antiparallel state of the magnetization in the recording layer 63 and the reference layer 65 can be read.

In the tenth embodiment of the present invention, the reference layer 65 includes any of the above-described respective various stacked films 10 (for example, the stacked film 10 according to the first embodiment of the present invention, the stacked film 10C illustrated in FIG. 3A, and the stacked film 10D illustrated in FIG. 3B). The reference layer 65 is configured to stack the first magnetic layer 11x, the antiferromagnetic coupling layer 12x, and the second magnetic layer 13x in this order. The first magnetic layer 11x and the second magnetic layer 13x are antiferromagnetically coupled. Thus, the reference layer 65 has a ferromagnetic pinned layer (SAF layer), and the perpendicular magnetic anisotropy of the first magnetic layer 11x and the second magnetic layer 13x is high. Accordingly, the thermal stability goes sufficiently well. As a result, the perpendicular magnetization of the first magnetic layer 11x and the second magnetic layer 13x can be more fixed and pinned. This can reduce write errors even when the element is miniaturized. Thus, the SOT-MRAM 60 has three terminals including the first terminal T1, the second terminal T2, and the third terminal T3. The SOT-MRAM 60 is configured such that the direction of magnetization in the recording layer 63 is reversed by a write current flowing through the conductive layer 62.

In the tenth embodiment of the present invention, the conductive layer 62 includes the stacked film 10B according to the third embodiment of the present invention. Therefore, in conductive layer 62, the perpendicular magnetic anisotropy of the first magnetic layer 11 and the second magnetic layer 13 increases, so the thermal stability goes sufficiently well. The spin Hall angle increases, and the first magnetic layer 11 is antiferromagnetically coupled to the second magnetic layer 13, thereby allowing a reduction in stray magnetic field.

In the tenth embodiment of the present invention, the conductive layer 62 may include the stacked film 10A according to the second embodiment of the present invention. That is, the conductive layer 62 has a stack structure of first magnetic layer 11/non-magnetic layer 12b/Ir—Re alloy layer (interlayer coupling layer) 12a/second magnetic layer 13. The spin Hall angle increases, and the first magnetic layer 11 is antiferromagnetically coupled to the second magnetic layer 13, thereby allowing a reduction in stray magnetic field. The conductive layer 62 may have a stack structure of first magnetic layer 11/Ir—Re alloy layer (interlayer coupling layer) 12a/non-magnetic layer 12b/second magnetic layer 13. Even in this case, the spin Hall angle increases, and the first magnetic layer 11 is antiferromagnetically coupled to the second magnetic layer 13, thereby allowing a reduction in stray magnetic field.

The following shows verification results and describes that in the stacked films 10, 10A, 10B, and the like according to the respective embodiments of the present invention, the interlayer coupling layer 12a preferably includes a layer made of an Ir—Re alloy and that the atom proportion of Re in the Ir—Re alloy is preferably more than 0% and about 12.5% or less.

### <Verification Experiment 1>

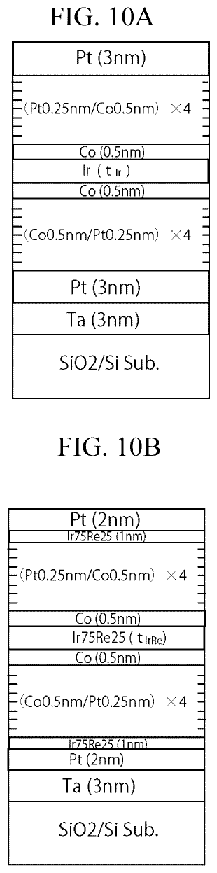

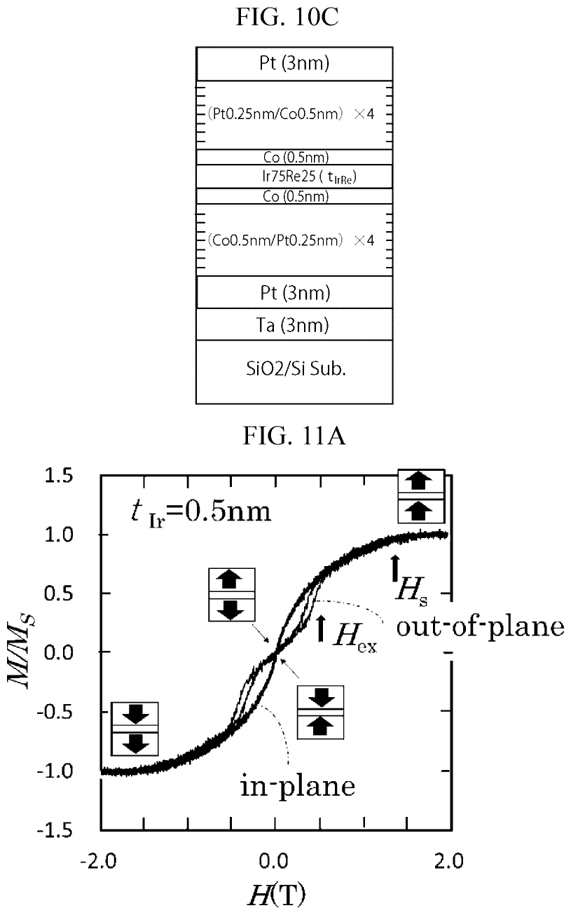

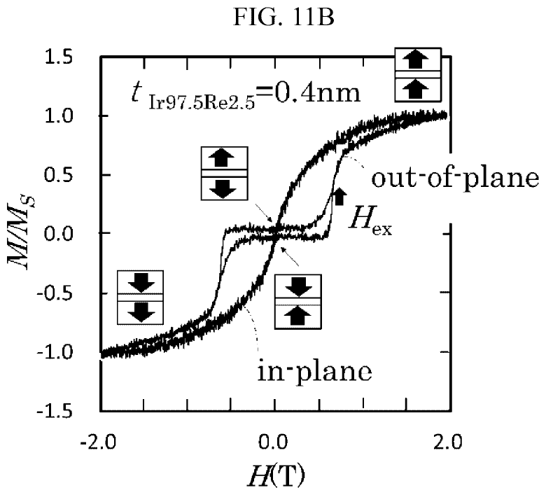

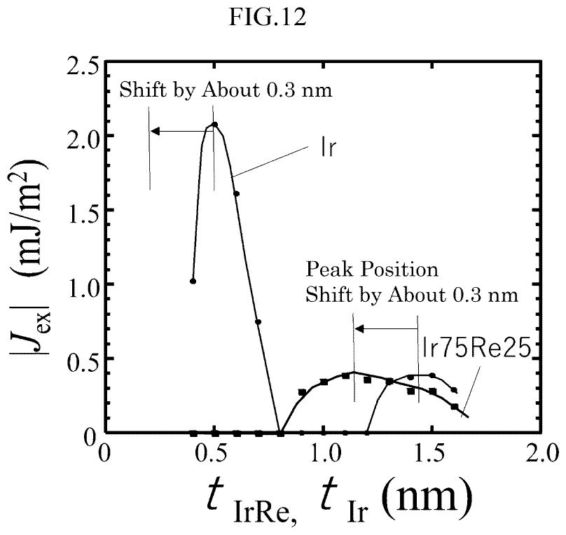

In Verification Experiment 1, using an Ir layer as an interlayer coupling layer, a plurality of samples were fabricated with a film thickness t_{Ir} of the Ir layer changed in 0.1 nm increments from 0.4 nm to 1.6 nm. The Ir layer was sandwiched by upper and lower 0.5 nm thick Co layers. FIG. 10A is a diagram illustrating a structure of the samples in Verification Experiment 1. Using a Si substrate having a thermal oxide film, a 3.0 nm thick Ta layer was disposed on the thermal oxide film; a 3.0 nm thick Pt layer was disposed on the Ta layer; four layers each of 0.5 nm thick Co layers and 0.25 nm thick Pt layers were alternately disposed on the Pt layer; further, a 0.5 nm thick Co layer, the Ir layer with the film thickness t_{Ir}, and a 0.5 nm thick Co layer were disposed in this order; additionally, four layers each of 0.25 nm thick Pt layers and 0.5 nm thick Co layers were alternately disposed; and a 3 nm thick Pt layer was further disposed.

### <Verification Experiment 2>

In Verification Experiment 2, using an Ir₇₅Re₂₅ layer as an interlayer coupling layer, a plurality of samples were fabricated with a film thickness t_{IrRe} of the Ir₇₅Re₂₅ layer changed in 0.1 nm increments from 0.4 nm to 1.6 nm. The Ir₇₅Re₂₅ layer was sandwiched by upper and lower 0.5 nm thick Co layers. FIG. 10B is a diagram illustrating a structure of the samples in Verification Experiment 2. Using a Si substrate having a thermal oxide film, a 3.0 nm thick Ta layer was disposed on the thermal oxide film; a 2.0 nm thick Pt layer was disposed on the Ta layer; a 1 nm thick Ir₇₅Re₂₅ layer was disposed on the Pt layer; four layers each of 0.5 nm thick Co layers and 0.25 nm thick Pt layers were alternately disposed on the Ir₇₅Re₂₅ layer; further, a 0.5 nm thick Co layer, the t_{IrRe} thick Ir₇₅Re₂₅ layer, and a 0.5 nm thick Co layer were disposed in this order; additionally, four layers each of 0.25 nm thick Pt layers and 0.5 nm thick Co layers were alternately disposed; and a 1 nm thick Ir₇₅Re₂₅ layer and a 3 nm thick Pt layer were further disposed in this order.

### <Verification Experiment 3>

In Verification Experiment 3, using an Ir₇₅Re₂₅ layer as an interlayer coupling layer, a plurality of samples were fabricated with a film thickness t_{IrRe} of the Ir₇₅Re₂₅ layer changed in 0.1 nm increments from 0.4 nm to 1.6 nm. The Ir₇₅Re₂₅ layer was sandwiched by upper and lower 0.5 nm thick Co layers. FIG. 10C is a diagram illustrating a structure of the samples in Verification Experiment 3. Using a Si substrate having a thermal oxide film, a 3.0 nm thick Ta layer was disposed on the thermal oxide film; a 3.0 nm thick Pt layer was disposed on the Ta layer; four layers each of 0.5 nm thick Co layers and 0.25 nm thick Pt layers were alternately disposed on the Pt layer; further, a 0.5 nm thick Co layer, the t_{IrRe} thick Ir₇₅Re₂₅ layer, and a 0.5 nm thick Co layer were disposed in this order; additionally, four layers each of 0.25 nm thick Pt layers and 0.5 nm thick Co layers were alternately disposed; and a 3 nm thick Pt layer was further disposed.

M-H curves (magnetization curves) were measured for each sample fabricated in Verification Experiments 1 to 3. FIG. 11A shows the M-H curves of the sample having the film thickness t_{Ir} of Ir of 0.5 nm in Verification Experiment 1. FIG. 11B shows M-H curves of the sample having a film thickness t_{IrRe} of Ir_{97.5}Re_{2.5} of 0.4 nm. The horizontal axis indicates an applied magnetic field H(T), and the vertical axis indicates M/Ms. Ms is a saturation value, and Hex is an exchange coupling magnetic field. The curve with in-plane indicates a case where an in-plane magnetic field was applied as the applied magnetic field, and the curve with out-of-plane indicates a case where a magnetic field perpendicular to the plane (perpendicular magnetic field) was applied.

From a comparison between FIG. 11A and FIG. 11B, it has been found that the interlayer coupling layer being formed of an Ir—Re alloy causes Hex to be large and keeps magnetization reversal from occurring unless an external magnetic field is increased, therefore increasing the exchange coupling strength between the upper and lower ferromagnetic layers. In addition, it has become clear that the perpendicular magnetic anisotropy is large when Re is mixed with Ir because the magnetic field where the magnetization increases in FIG. 11B is steep compared with the magnetization curves in FIG. 11A.

In each sample fabricated in Verification Experiments 1 to 3, an interlayer exchange coupling Jₑₓ (mJ/m²) was determined. The measurement environment was set to room temperature. FIG. 12 is a drawing showing the dependence of an interlayer interaction on a film thickness of Ir or IrRe concerning Verification Experiment 1 and Verification Experiment 2. The horizontal axis of the drawing indicates a film thickness, which is the film thickness t_{Ir} of Ir or the film thickness t_{IrRe} of IrRe, and the vertical axis indicates the magnitude of interlayer exchange coupling |Jₑₓ|. The black circle (●) plots indicate data in a case where the interlayer coupling layer is an Ir layer, and the black square (▪) plots indicate data in a case where the interlayer coupling layer is an Ir₇₅Re₂₅ layer.

In the IrRe interlayer coupling layer as shown in Verification Experiment 2, a shift in the peak position of an antiparallel array (AF) to a thin layer side by about 0.3 nm (shift to the left side of the drawing) was observed compared with a case of the Ir interlayer coupling layer in Verification Experiment 1. When the concentration of Re was high at 25%, the shift amount was large, and the first peak was not observed.

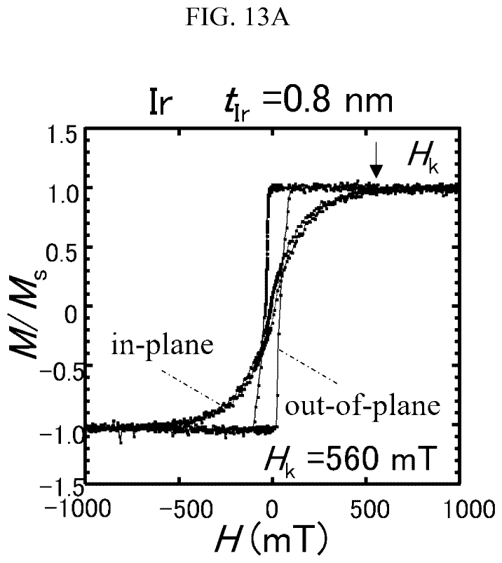

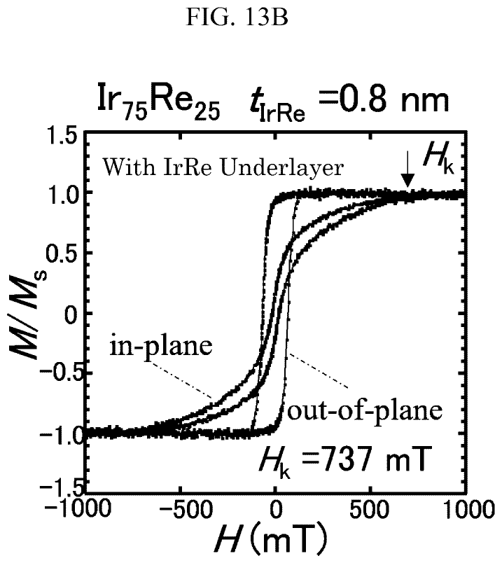

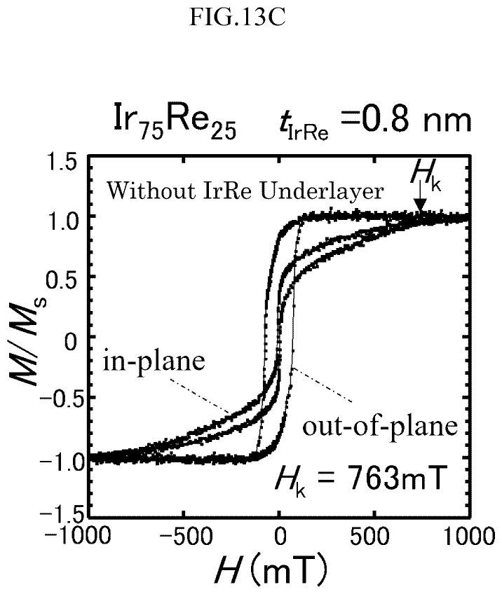

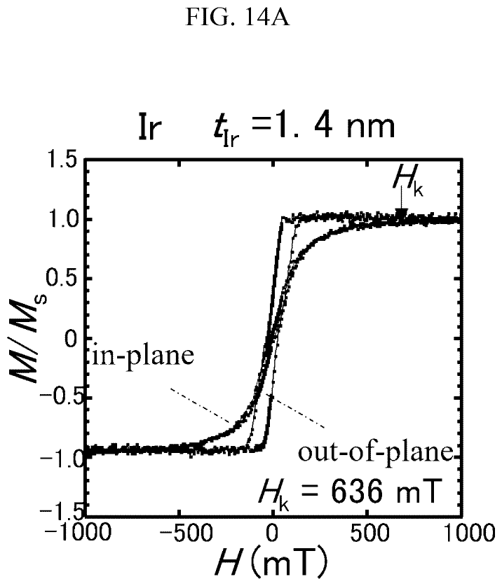

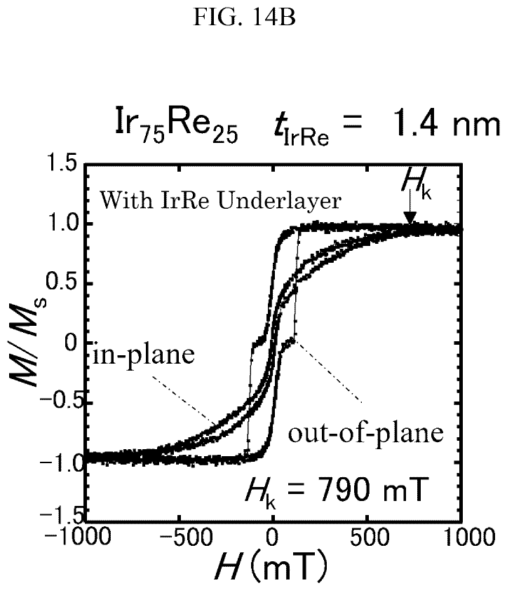

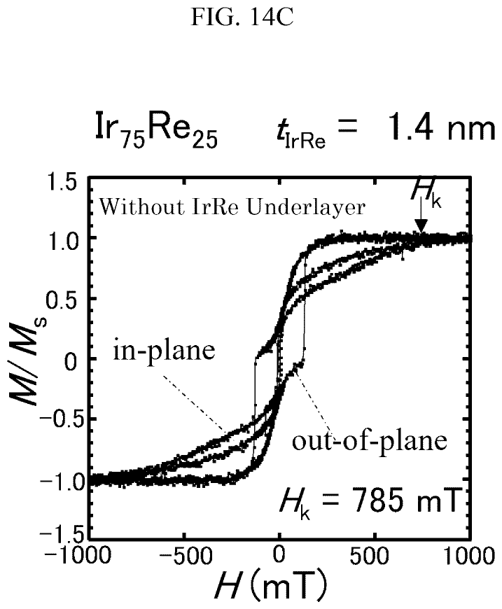

FIGS. 13A to 13C show the M-H curves of the respective samples of Verification Experiments 1 to 3 having a thickness of the interlayer coupling layers of 0.8 nm. FIGS. 14A to 14C show the M-H curves of the respective samples of Verification Experiments 1 to 3 having a thickness of the interlayer coupling layers of 1.4 nm. The horizontal axis indicates an applied magnetic field H(T), and the vertical axis indicates M/Ms. Ms is a saturation value. The curve with in-plane indicates a case where an in-plane magnetic field was applied as the applied magnetic field, and the curve with out-of-plane indicates a case where a magnetic field perpendicular to the plane (perpendicular magnetic field) was applied.

As can be seen from FIGS. 13A to 13C, when the thicknesses t_{Ir} and t_{IrRe} of the interlayer coupling layers are 0.8 nm, the upper and lower Co layers are ferromagnetically coupled, and as can be seen from FIGS. 14A to 14C, when the thicknesses t_{Ir} and t_{IrRe} of the interlayer coupling layers are 1.4 nm, the upper and lower Co layers are antiferromagnetically coupled.

It has been found that, in the ferromagnetically coupled state, when the thicknesses t_{Ir} and t_{IrRe} of the interlayer coupling layers are 0.8 nm, an anisotropic magnetic field Hₖ becomes large and the perpendicular magnetic anisotropy increases in the case where the interlayer coupling layer is the Ir₇₅Re₂₅ layer, compared with the case where the interlayer coupling layer is the Ir layer.

It has been found that, in the antiferromagnetically coupled state, when the thicknesses t_{Ir} and t_{IrRe} of the interlayer coupling layers are 1.4 nm, the anisotropic magnetic field Hₖ becomes large and the perpendicular magnetic anisotropy increases in the case where the interlayer coupling layer is the Ir₇₅Re₂₅ layer, compared with the case where the interlayer coupling layer is the Ir layer.

Therefore, it was possible to confirm the increase in Hₖ of M-H in a Hard axis direction in both the ferromagnetically coupled state and the antiferromagnetically coupled state. Accordingly, it was possible to confirm the increase in the perpendicular magnetic anisotropy.

It has been found that the presence or absence of the IrRe layer does not affect the increase in the perpendicular magnetic anisotropy when an underlayer of an IrRe alloy is disposed, as in the samples fabricated in Verification Experiment 2, compared with a case without an underlayer as in the samples fabricated in Verification Experiment 3.

### <Verification Experiment 4>

In Verification Experiment 4, an IrₓRe_{y} layer was used as the interlayer coupling layer. For x and y, a case where x=98.5 and y=1.5, a case where x=97.5 and y=2.5, a case where x=95.5 and y=4.5, a case where x=91.5 and y=8.5, a case where x=83.5 and y=16.5, and a case where x=100 and y=0 as a comparative example were set. A plurality of samples were fabricated with the film thickness t_{IrRe} of the IrₓRe_{y} layer changed in 0.1 nm or 0.05 nm increments from 0.3 nm to 0.6 nm. The IrₓRe_{y} layer was sandwiched by upper and lower 0.5 nm thick Co layers.

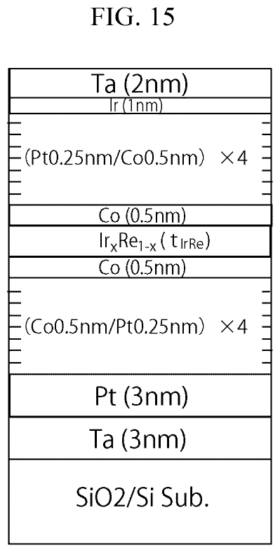

FIG. 15 is a diagram illustrating a structure of the samples in Verification Experiment 4. Using a Si substrate having a thermal oxide film, a 3.0 nm thick Ta layer was disposed on the thermal oxide film; a 3.0 nm thick Pt layer was disposed on the Ta layer; four layers each of 0.5 nm thick Co layers and 0.25 nm thick Pt layers were alternately disposed on the Pt layer; further, a 0.5 nm thick Co layer, a t_{IrRe} thick IrₓRe_{y} layer, and a 0.5 nm thick Co layer were disposed in this order; additionally, four layers each of 0.25 nm thick Pt layers and 0.5 nm thick Co layers were alternately disposed; and a 1 nm thick Ir layer and a 2 nm thick Ta layer were further disposed. FIG. 11B shows the M-H curves of the sample having the film thickness t_{IrRe} of Ir_{97.5}Re_{2.5} of 0.4 nm in the sample shown in FIG. 15.

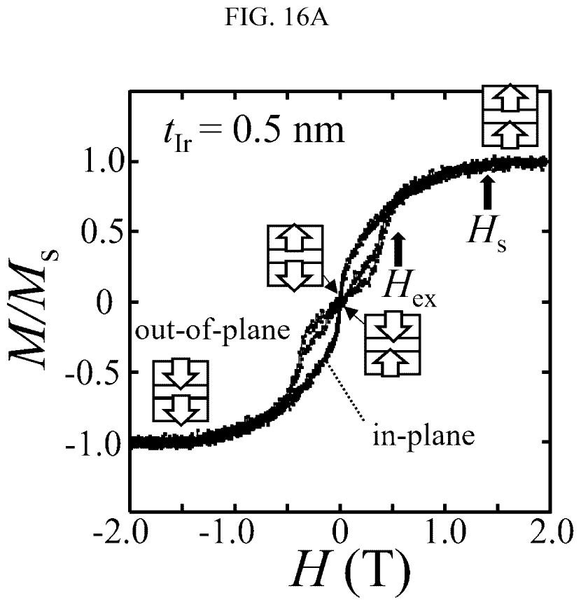

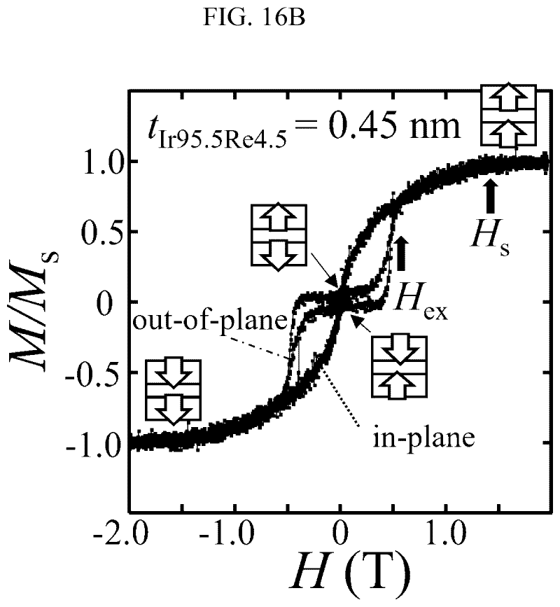

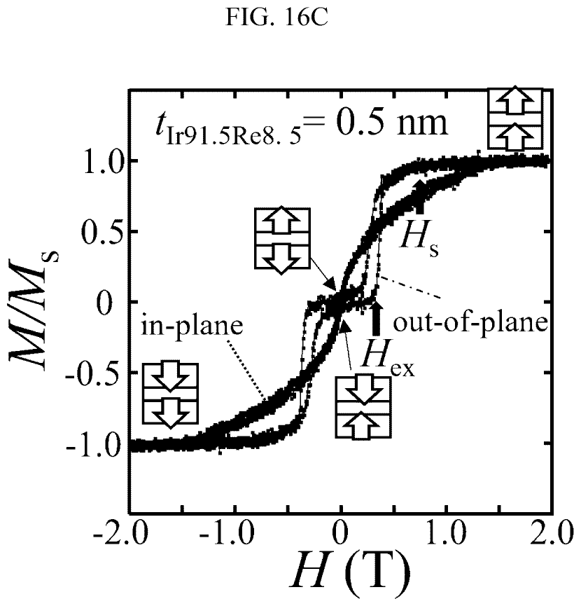

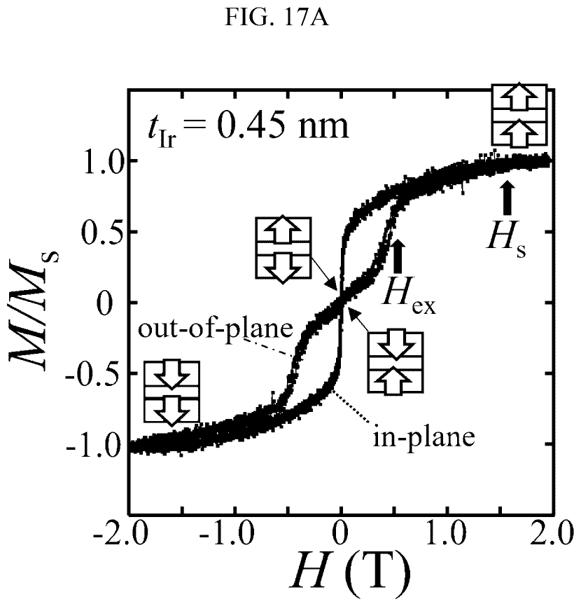

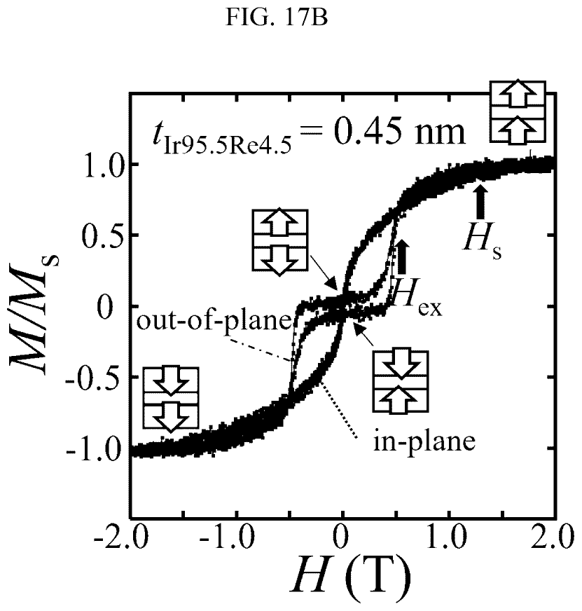

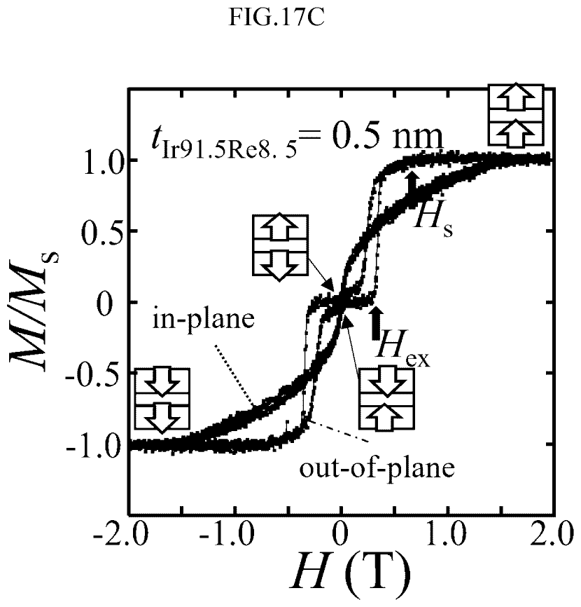

FIG. 16A shows an M-H measurement result after annealing a sample, in which the interlayer coupling layer is an Ir layer having a thickness of 0.5 nm and antiferromagnetic coupling occurs, in a vacuum at 300° C. for one hour. FIG. 16B shows an M-H measurement result after annealing a sample, in which the interlayer coupling layer is an Ir_{95.5}Re_{4.5} layer having a thickness of 0.45 nm and antiferromagnetic coupling occurs, in a vacuum at 300° C. for one hour. FIG. 16C shows an M-H measurement result after annealing a sample, in which the interlayer coupling layer is an Ir_{91.5}Re_{8.5} layer having a thickness of 0.5 nm and antiferromagnetic coupling occurs, in a vacuum at 300° C. for one hour. FIG. 17A shows an M-H measurement result after annealing a sample, in which the interlayer coupling layer is an Ir layer having a thickness of 0.45 nm and antiferromagnetic coupling occurs, in a vacuum at 400° C. for one hour. FIG. 17B shows an M-H measurement result after annealing a sample, in which the interlayer coupling layer is an Ir_{95.5}Re₄₅ layer having a thickness of 0.45 nm and antiferromagnetic coupling occurs, in a vacuum at 400° C. for one hour. FIG. 17C shows an M-H measurement result after annealing a sample, in which the interlayer coupling layer is an Ir_{91.5}Re_{8.5} layer having a thickness of 0.5 nm and antiferromagnetic coupling occurs, in a vacuum at 400° C. for one hour. The thickness of the interlayer coupling layer is a thickness at the first peak.

From FIGS. 16A to 16C and FIGS. 17A to 17C, it has been found that the perpendicular magnetic anisotropy strengthens when the interlayer coupling layer is IrRe compared with the case where the interlayer coupling layer is Ir. Similar results were obtained for samples not shown in FIGS. 16A to 16C and FIGS. 17A to 17C.

FIG. 18A is a drawing showing the dependence of the interlayer exchange coupling |Jₑₓ| (mJ/m²) of the film thickness t_{IrRe} of IrRe on the film thickness t_{IrRe} of IrRe concerning the samples annealed in a vacuum at 300° C. for one hour in Verification Experiment 4. FIG. 18B is a drawing showing the dependence of the interlayer exchange coupling |Jₑₓ| (mJ/m²) of the film thickness t_{IrRe} of IrRe on the film thickness t_{IrRe} of IrRe concerning the samples annealed in a vacuum at 400° C. for one hour in Verification Experiment 4. Table 1 shows the interlayer exchange coupling |Jₑₓ| (mJ/m²) of each sample when it was annealed at 300° C. for one hour with the interlayer coupling layer being constituted of IrₓRe_{y}. Table 2 shows the interlayer exchange coupling |Jₑₓ| (mJ/m²) of each sample when it was annealed at 400° C. for one hour with the interlayer coupling layer being constituted of IrₓRe_{y}. In Tables 1 and 2, “-” indicates that no sample was prepared.

It has been found that, since t_{IrRe} is the value at the first peak at which AF coupling occurs, the interlayer coupling strength is high as long as the composition of the interlayer coupling layer contains a small amount of Re with Ir.

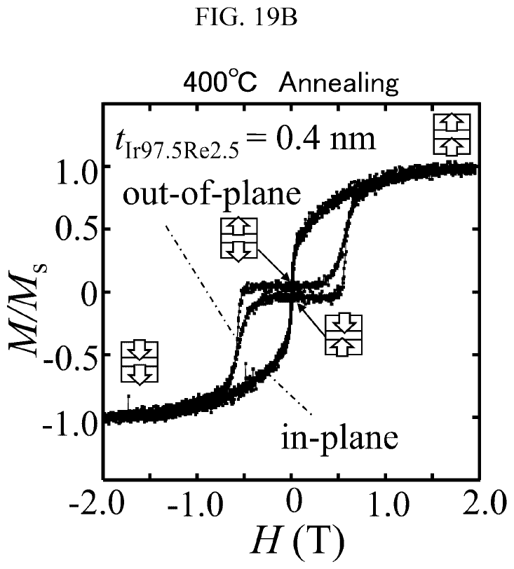

FIG. 19A shows an M-H measurement result after annealing a sample having an interlayer coupling layer Ir_{97.5}Re_{2.5} with the film thickness t_{IrRe} of 0.4 nm at 300° C. FIG. 19B shows an M-H measurement result after annealing a sample having an interlayer coupling layer Ir_{97.5}Re_{2.5} with the film thickness t_{IrRe} of 0.4 nm at 400° C. It was possible to confirm that the magnetic layers exhibited perpendicular magnetic anisotropy, and antiferromagnetic coupling occurred between Co in the magnetic layers.

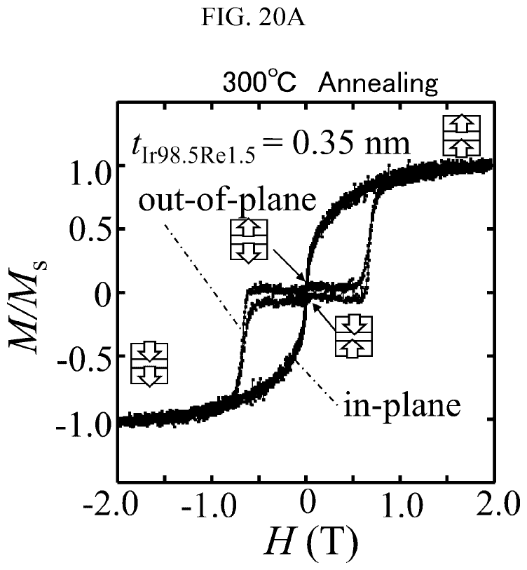

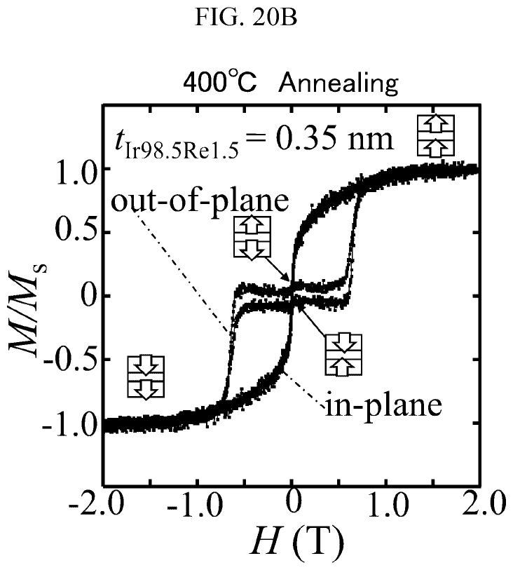

FIG. 20A shows an M-H measurement result after annealing a sample having an interlayer coupling layer Ir_{98.5}Re_{1.5} with the film thickness t_{IrRe} of 0.35 nm at 300° C. FIG. 20B shows an M-H measurement result after annealing a sample having an interlayer coupling layer Ir_{98.5}Re_{1.5} with the film thickness t_{IrRe} of 0.35 nm at 400° C. It was possible to confirm that the magnetic layers exhibited perpendicular magnetic anisotropy, and antiferromagnetic coupling occurred between Co in the magnetic layers. It was possible to confirm that annealing tolerance at 400° C. of the sample having the Ir_{98.5}Re_{1.5} layer as the interlayer coupling layer was improved compared with the sample having the Ir_{97.5}Re_{2.5} layer as the interlayer coupling layer. Therefore, the stacked films according to the embodiments of the present invention have annealing tolerance at 300° C. to 400° C.

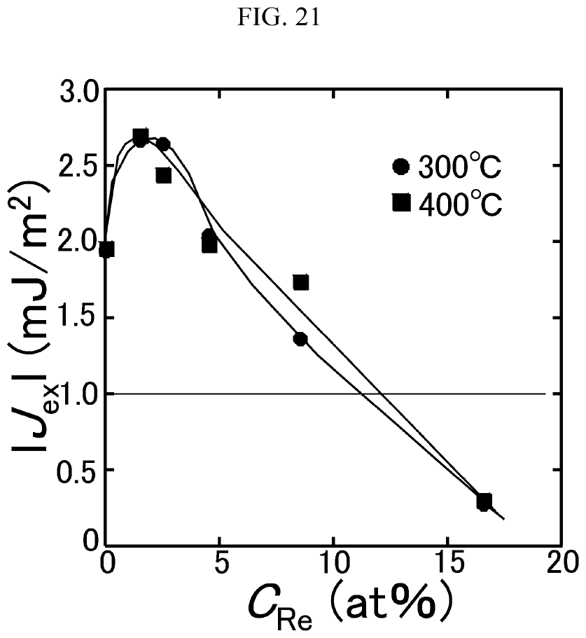

FIG. 21 is a drawing showing the dependence of interlayer coupling strength on a Re composition. The horizontal axis indicates the composition (concentration) of Re in atomic percent, and the vertical axis indicates the magnitude of interlayer exchange coupling |Jₑₓ| (mJ/m²). The black circle (●) plots relate to the samples annealed at 300° C., and the black square (▪) plots relate to the samples annealed at 400° C.

The interlayer exchange coupling |Jₑₓ| of 1.0 (mJ/m²) is a sufficient value. When the interlayer coupling layer is IrₓRe_{y} (where x+y=100, 0<x, y<100), 0<y≤12.5 is preferable. The value of y is preferably 10 or less. It is preferable that y is 8.5 or less. The value of y is further preferably 4.5 or less. It is only necessary to contain Re, and as the minimum value of y, y is preferably 0.05 or more. The value of y is further preferably 0.1 or more.

TABLE 1

| t_{IrRe} (nm) | 0.3 | 0.35 | 0.4 | 0.45 | 0.5 | 0.55 | 0.6 |
|---|---|---|---|---|---|---|---|
| y = 0 | 0 | — | 1.05 | 1.87 | 1.94 | 1.72 | 1.28 |
| y = 1.5 | 0.85 | 2.67 | 2.45 | 2.52 | 2.01 | 1.49 | 0.97 |
| y = 2.5 | 0.39 | 2.01 | 2.64 | 2.19 | 2.01 | 1.64 | 0.81 |
| y = 4.5 | 0 | — | 1.15 | 2.04 | 1.72 | 1.43 | 1.01 |
| y = 8.5 | 0 | — | 0.58 | 1.27 | 1.37 | 0.79 | 0.65 |
| y = 16.5 | 0 | — | 0 | — | 0.28 | — | 0 |

TABLE 2

| t_{IrRe} (nm) | 0.3 | 0.35 | 0.4 | 0.45 | 0.5 | 0.55 | 0.6 |
|---|---|---|---|---|---|---|---|
| y = 0 | 0 | — | 1.09 | 1.96 | 1.86 | 1.76 | 1.29 |
| y = 1.5 | 0.85 | 2.55 | 2.17 | 2.38 | 1.91 | 1.26 | 0.93 |
| y = 2.5 | 0 | 1.82 | 2.44 | 2.2 | 2 | 1.59 | 0.39 |
| y = 4.5 | 0 | — | 0.77 | 1.98 | 1.5 | 1.18 | 0.98 |
| y = 8.5 | 0 | — | 0.37 | 1.16 | 1.74 | 0.79 | 0.57 |
| y = 16.5 | 0 | — | 0 | — | 0.31 | — | 0 |

As described above, since the interlayer coupling strength is preferably 1.0 mJ/m² or more, the following film thickness ranges can be used.

In the interlayer coupling layer IrₓRe_{y}, y=1.5, and the film thickness t_{Irx}R_{ey} is preferably more than 0.3 nm and 0.6 nm or less.

In the interlayer coupling layer IrₓRe_{y}, y=2.5, and the film thickness t_{Irx}R_{ey} is preferably 0.35 nm or more and 0.55 nm or less.

In the interlayer coupling layer IrₓRe_{y}, y=4.5, and the film thickness t_{Irx}R_{ey} is preferably more than 0.4 nm and 0.55 nm or less.

In the interlayer coupling layer IrₓRe_{y}, y=8.5, and the film thickness t_{Irx}R_{ey} is preferably 0.45 nm or more and less than 0.55 nm.

Even using an Ru layer or Ir layer of a publicly-known example, the interlayer coupling strength of 1.0 mJ/m² or more can be obtained within the above film thickness ranges. However, when IrRe is used, more favorable results can be obtained for the perpendicular magnetic anisotropy and annealing tolerance at 400° C.

In addition, in the film thickness ranges of the following compositions, the interlayer coupling strength is greater than that of the case of using an Ir layer of a publicly-known example, and more favorable effects can be obtained.

In the interlayer coupling layer IrₓRe_{y}, y=1.5, and the film thickness t_{Irx}R_{ey} is preferably 0.32 nm or more and 0.5 nm or less.

In the interlayer coupling layer IrₓRe_{y}, y=2.5, and the film thickness t_{Irx}R_{ey} is preferably 0.35 nm or more and 0.5 nm or less.

In the interlayer coupling layer IrₓRe_{y}, y=4.5, and the film thickness t_{Irx}R_{ey} is preferably 0.45 nm.

### <Verification Experiment 5>

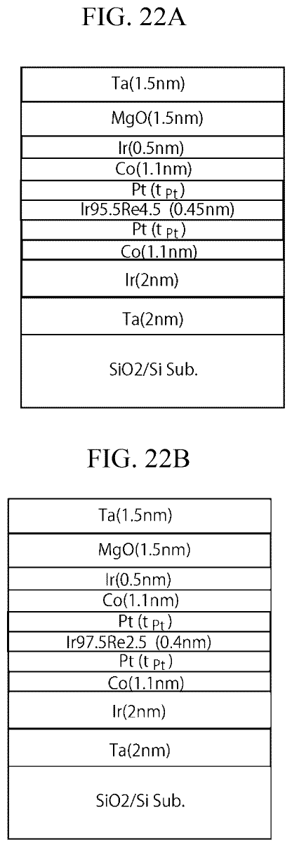

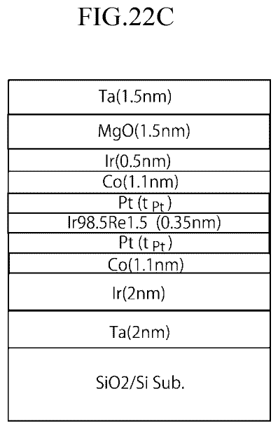

As Verification Experiment 5, several samples were fabricated assuming conductive layers for SOT-MRAM (wiring layers for SOT-MRAM). An interlayer coupling layer Ir_{95.5}Re_{4.5} with a thickness of 0.45 nm was used to fabricate each sample in which upper and lower two Pt layers sandwiching the interlayer coupling layer had a thickness of 0.4 nm or 0.5 nm. FIG. 22A is a diagram illustrating a structure of the samples in Verification Experiment 5. Using a Si substrate having a thermal oxide film, a 2.0 nm thick Ta layer was disposed on the thermal oxide film; a 2.0 nm thick Ir layer was disposed on the Ta layer; a 1.1 nm thick Co layer was disposed on the Ir layer; a Pt layer with a thickness tri was disposed on the Co layer; the 0.45 nm thick Ir_{95.5}Re_{4.5} layer was disposed on the Pt layer; a Pt layer with the thickness t_{Pt} was disposed on the Ir_{95.5}Re_{4.5} layer; a 1.1 nm thick Co layer was disposed on the Pt layer; a 0.5 nm thick Ir layer was disposed on the Co layer; a 1.5 nm thick MgO layer was disposed on the Ir layer; and a 1.5 nm thick Ta layer was disposed on the MgO layer.

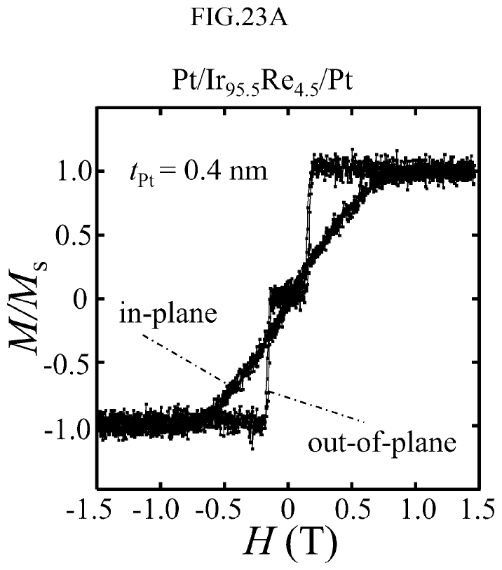

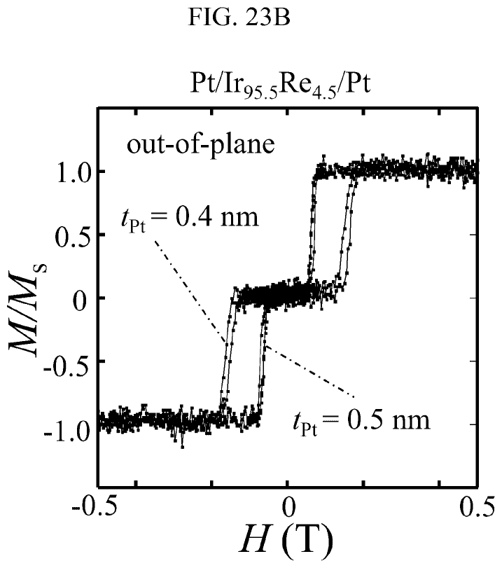

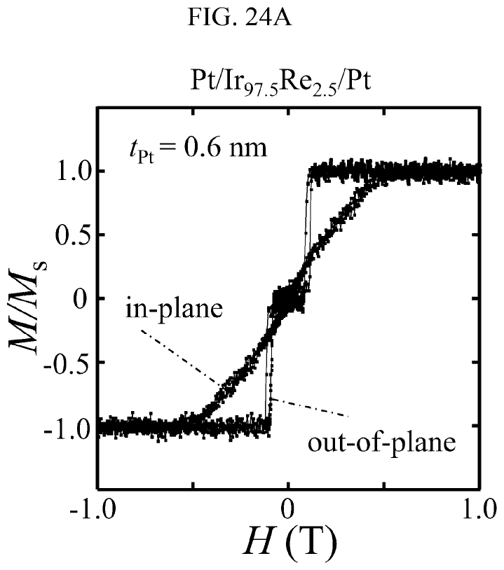

FIG. 23A shows M-H curves of the sample having the Pt layers with the thickness t_{Pt} of 0.4 nm and the interlayer coupling layer Ir_{95.5}Re_{4.5}. It was possible to confirm that the magnetic layers exhibited perpendicular magnetic anisotropy.

FIG. 23B shows M-H curves of two samples having the interlayer coupling layer Ir_{95.5}Re_{4.5}. The sample having the Pt layers with the thickness t_{Pt} of 0.4 nm and the sample having the Pt layers with the thickness tri of 0.5 nm are shown. It was possible to confirm that the magnetic layers exhibited satisfactory perpendicular magnetic anisotropy and antiferromagnetic coupling.

### <Verification Experiment 6>

As Verification Experiment 6, several samples were fabricated assuming conductive layers for SOT-MRAM. An interlayer coupling layer Ir_{97.5}Re_{2.5} with a thickness of 0.4 nm was used to fabricate each sample in which upper and lower two Pt layers sandwiching the interlayer coupling layer had a thickness of 0.6 nm, 0.7 nm, or 0.8 nm. FIG. 22B is a diagram illustrating a structure of the samples in Verification Experiment 6. Using a Si substrate having a thermal oxide film, a 2.0 nm thick Ta layer was disposed on the thermal oxide film; a 2.0 nm thick Ir layer was disposed on the Ta layer; a 1.1 nm thick Co layer was disposed on the Ir layer; a Pt layer with a thickness t_{Pt} was disposed on the Co layer; the 0.4 nm thick Ir_{97.5}Re_{2.5} layer was disposed on the Pt layer; a Pt layer with the thickness t_{Pt} was disposed on the Ir_{97.5}Re_{2.5} layer; a 1.1 nm thick Co layer was disposed on the Pt layer; a 0.5 nm thick Ir layer was disposed on the Co layer; a 1.5 nm thick MgO layer was disposed on the Ir layer; and a 1.5 nm thick Ta layer was disposed on the MgO layer.

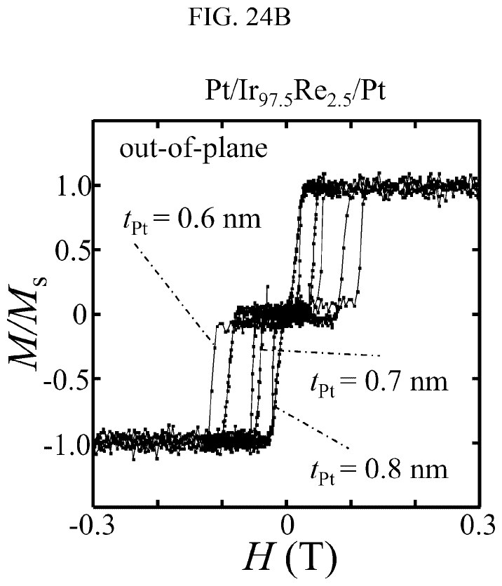

FIG. 24A shows M-H curves of the sample having the Pt layers with the thickness tri of 0.6 nm and the interlayer coupling layer Ir_{97.5}Re_{2.5} layer. It was possible to confirm that the magnetic layers exhibited perpendicular magnetic anisotropy.

FIG. 24B shows M-H curves of three samples having the interlayer coupling layer Ir_{97.5}Re_{2.5}. The sample having the Pt layers with the thickness tri of 0.6 nm, the sample having the Pt layers with the thickness t_{Pt} of 0.7 nm, and the sample having the Pt layers with the thickness t_{Pt} of 0.8 nm are shown. It was possible to confirm that the magnetic layers exhibited satisfactory perpendicular magnetic anisotropy and antiferromagnetic coupling in any of the samples.

### <Verification Experiment 7>

As Verification Experiment 7, several samples were fabricated assuming conductive layers for SOT-MRAM. An interlayer coupling layer Ir_{98.5}Re_{1.5} with a thickness of 0.35 nm was used to fabricate each sample in which upper and lower two Pt layers sandwiching the interlayer coupling layer had a thickness of 0.6 nm, 0.7 nm, or 0.8 nm. FIG. 22C is a diagram illustrating a structure of the samples in Verification Experiment 7. Using a Si substrate having a thermal oxide film, a 2.0 nm thick Ta layer was disposed on the thermal oxide film; a 2.0 nm thick Ir layer was disposed on the Ta layer; a 1.1 nm thick Co layer was disposed on the Ir layer; a Pt layer with a thickness tri was disposed on the Co layer; the 0.35 nm thick Ir_{98.5}Re_{1.5} layer was disposed on the Pt layer; a Pt layer with the thickness tri was disposed on the Ir_{98.5}Re_{1.5} layer; a 1.1 nm thick Co layer was disposed on the Pt layer; a 0.5 nm thick Ir layer was disposed on the Co layer; a 1.5 nm thick MgO layer was disposed on the Ir layer; and a 1.5 nm thick Ta layer was disposed on the MgO layer.

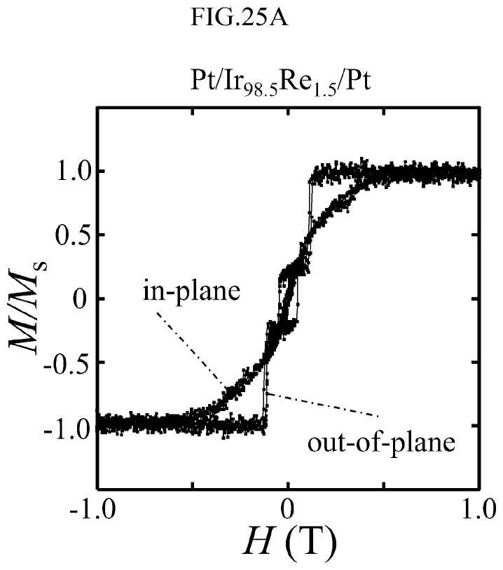

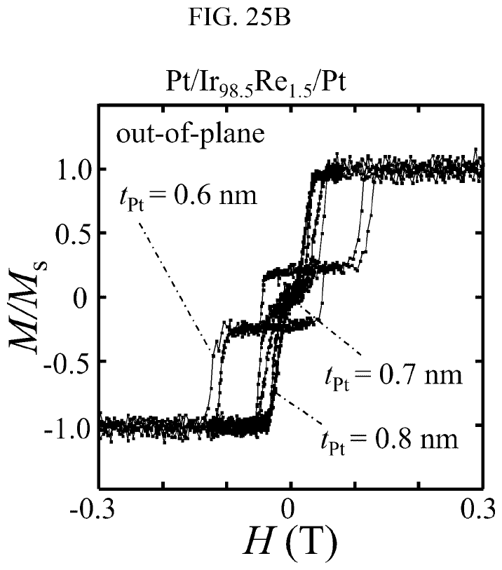

FIG. 25A shows M-H curves of the sample having the Pt layers with the thickness tri of 0.6 nm and the interlayer coupling layer Ir_{98.5}Re_{1.5} layer. It was possible to confirm that the magnetic layers exhibited satisfactory perpendicular magnetic anisotropy and antiferromagnetic coupling.

FIG. 25B shows M-H curves of three samples having the interlayer coupling layer Ir_{98.5}Re_{1.5}. The sample having the Pt layers with the thickness tri of 0.6 nm, the sample having the Pt layers with the thickness t_{Pt} of 0.7 nm, and the sample having the Pt layers with the thickness t_{Pt} of 0.8 nm are shown. It was possible to confirm that the magnetic layers exhibited satisfactory perpendicular magnetic anisotropy and antiferromagnetic coupling in any of the samples.

As a result of Verification Experiments 5 to 7, it has been found that a stacked film having an IrₓRe_{y} layer (0<y<4.5) as an interlayer coupling layer can be used as a conductive layer for SOT-MRAM.

A plurality of samples were fabricated as follows. As described in the fourth embodiment of the present invention, using an Ir layer as the non-magnetic layer 12d, the thickness of the non-magnetic layer 12d and the composition of Re in the layer 12a containing an Ir—Re alloy were adjusted such that the composition of Ir and Re when the layer 12a containing an Ir—Re alloy and the non-magnetic layer 12d were viewed as one layer was consistent with the preferred composition in the first embodiment of the present invention. In addition, the antiferromagnetic coupling layer 12 was set in a thickness range preferable in a case where the non-magnetic layer 12d was not used. Even in this case, it was confirmed that the perpendicular magnetic anisotropy increased, and the thermal stability was good, similarly to the case where the non-magnetic layer 12d was not used.

A plurality of samples were fabricated as follows. As described in the fifth embodiment of the present invention, using an Ir layer as both the first non-magnetic layer 12d and the second non-magnetic layer 12e, the thicknesses of the first non-magnetic layer 12d and the second non-magnetic layer 12e and the composition of Re in the layer 12a containing an Ir—Re alloy were adjusted such that the composition of Ir and Re when the layer 12a containing an Ir—Re alloy, the first non-magnetic layer 12d, and the second non-magnetic layer 12e were viewed as one layer was consistent with the preferred composition in the first embodiment of the present invention. In addition, the antiferromagnetic coupling layer 12 was set in a thickness range preferable in a case where any of the first non-magnetic layer 12d and the second non-magnetic layer 12e was not used. Even in this case, it was confirmed that the perpendicular magnetic anisotropy increased, and the thermal stability was good, similarly to the case where the non-magnetic layer 12d was not used.

A semiconductor memory including an MRAM and a logic LSI according to the embodiments of the present invention can be configured by using a stacked film according to the first to fifth embodiments of the present invention and including a plurality of magnetoresistive effect elements according to the sixth to tenth embodiments of the present invention (including an SOT-MRAM). The stacked film according to the first to fifth embodiments of the present invention is used in each of the magnetoresistive effect elements according to the embodiments of the present invention, the semiconductor memory including an MRAM according to the embodiments of the present invention, and the logic LSI according to the embodiments of the present invention. Therefore, the thickness of the layer containing Ir and Re in the antiferromagnetic coupling layer 12 (for example, the interlayer coupling layer 12a, the layer constituted of the interlayer coupling layer 12a and the non-magnetic layer 12d, and the layer constituted of the non-magnetic layer 12d, the interlayer coupling layer 12a, and the non-magnetic layer 12e) in the magnetoresistive effect elements according to the embodiments of the present invention, the semiconductor memory including an MRAM according to the embodiments of the present invention, and the logic LSI according to the embodiments of the present invention is more than 0.2 nm and less than 1.0 nm, which is similar to those described in the first embodiment in detail. The magnetoresistive effect elements, the semiconductor memory, and the logic LSI have one or a plurality of stacked films according to the embodiments of the present invention.

### <Comparative Experiment 1>

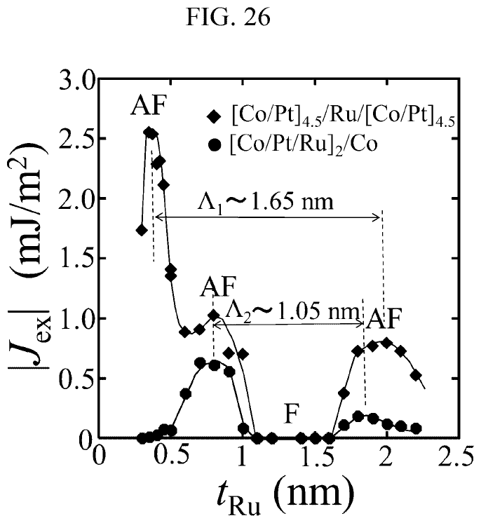

As Comparative Experiment 1, concerning a plurality of samples in which the interlayer coupling layers were Ru layers with different thicknesses, samples having (Co/Pt/Ru)₂/Co and samples having (Co/Pt)_{4.5}/Ru/(Co/Pt)_{4.5} were fabricated to measure the interlayer exchange coupling |Jₑₓ|. FIG. 26 shows the dependence of the interlayer exchange coupling |Jₑₓ| on the Ru thickness. The horizontal axis indicates the thickness (nm) of the Ru layer and the vertical axis indicates the magnitude of interlayer exchange coupling |Jₑₓ|. The black circle plots relate to (Co/Pt/Ru)₂/Co and the diamond plots relate to (Co/Pt)_{4.5}/Ru/(Co/Pt)_{4.5}. Thicknesses t_{Ru} of the Ru layers of the respective plots are 0.4 nm, 0.5 nm, 0.6 nm, 0.7 nm, 0.8 nm, 0.9 nm, 1.0 nm, 1.1 nm, 1.2 nm, 1.4 nm, 1.5 nm, 1.6 nm, 1.7 nm, 1.8 nm, 1.9 nm, 2.0 nm, 2.1 nm, and 2.2 nm. It has been found that when Pt is interposed, oscillation corresponding to an interlayer exchange oscillation period Λ1 caused by interaction between the Ru layers disappears. Therefore, when Pt is diffused so as to come into contact with Co during heat treatment at 400° C., a large variation is caused in the interlayer coupling strength. Accordingly, when the Ru layer is used as the interlayer coupling layer, as the thickness of Ru, a thickness at which the interlayer exchange coupling |Jₑₓ| has the second peak needs to be selected.

In contrast to this, as illustrated in FIG. 18A and FIG. 18B described above, since the interlayer coupling layer is constituted of the Ir—Re alloy containing a small amount of Re with Ir, the thickness at the first peak can be selected.

### <Comparative Experiment 2>

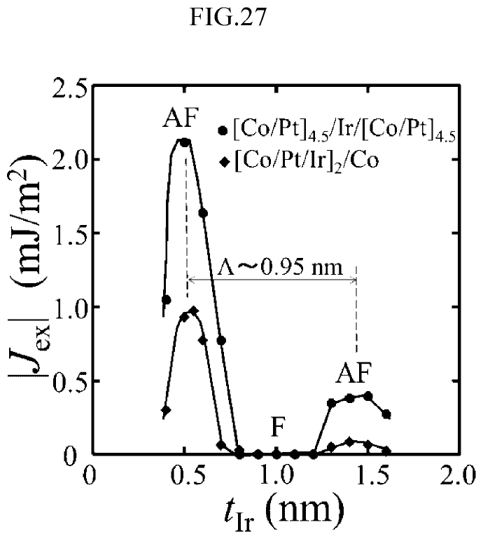

As Comparative Experiment 2, concerning a plurality of samples in which the interlayer coupling layers were Ir layers with different thicknesses, samples having (Co/Pt/Ir)₂/Co and samples having (Co/Pt)_{4.5}/Ir/(Co/Pt)_{4.5} were fabricated to measure the interlayer exchange coupling |Jₑₓ|. FIG. 27 shows the dependence of the interlayer exchange coupling |Jₑₓ| on the Ir thickness. The horizontal axis indicates the thickness (nm) of the Ir layer, and the vertical axis indicates the magnitude of interlayer exchange coupling |Jₑₓ|. The black circle plots relate to (Co/Pt)_{4.5}/Ir/(Co/Pt)_{4.5} and the diamond plots relate to (Co/Pt/Ir)₂/Co. Thicknesses t_{Ir} of the Ir layers of the respective plots are in increments of 0.1 nm like 0.4 nm, 0.5 nm, 0.6 nm, 0.7 nm, 0.8 nm, 0.9 nm, 1.0 nm, 1.1 nm, 1.2 nm, 1.3 nm, 1.4 nm, 1.5 nm, and 1.6 nm, and only the diamond plots include 0.55 nm. It has been found that even when the Pt layer as the non-magnetic layer is inserted between the interlayer coupling layer and the ferromagnetic layer, the interlayer exchange coupling |Jₑₓ| keeps the antiferromagnetic coupling.

When FIG. 26 is compared with FIG. 27, the exchange coupling strength between the first magnetic layer and the second magnetic layer via the interlayer coupling layer constituted of the Ru layer is stronger than the exchange coupling strength between the first magnetic layer and the second magnetic layer via the coupling layer constituted of the Ir layer. However, when the atom Ru constituting the interlayer coupling layer comes into contact with Pt constituting a part of the first magnetic layer or a part of the second magnetic layer, even if only slightly, the interlayer exchange coupling strength between the first magnetic layer and the second magnetic layer by the interlayer coupling layer weakens, resulting in poor thermal stability.

When the interlayer coupling layer is a layer made only of Ir, the disappearance of the first peak does not occur as when the interlayer coupling layer is a layer made only of Ru. However, Ir is known to be expensive as a material for the interlayer coupling layer. Since Re is inexpensive compared with Ir, it also has the advantage of being able to reduce the mass production cost. In the stacked films according to the embodiments of the present invention, the interlayer coupling layer 12a is configured to include a layer made of an alloy of Ir and Re. Accordingly, the interlayer coupling layer 12a has high exchange coupling strength between the first magnetic layer 11 and the second magnetic layer 13, increasing perpendicular magnetic anisotropy and having good stability. In addition, the stacked films have annealing tolerance at 400° C.

### <Verification Experiment 8>

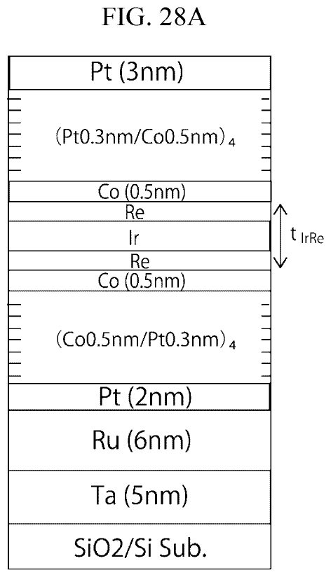

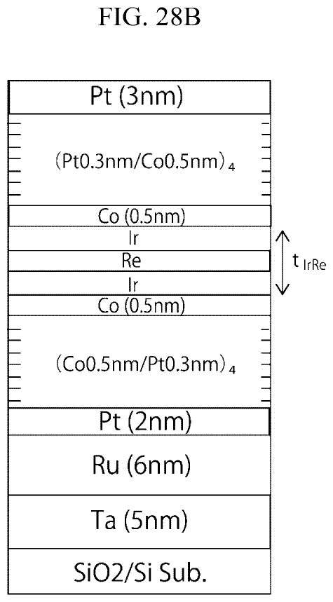

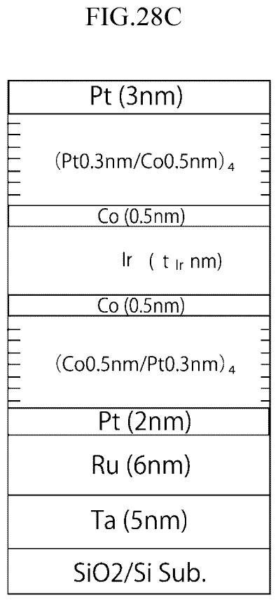

In Verification Experiment 8, using the antiferromagnetic coupling layer as a Re/Ir/Re stacked structure, with the atom proportion of Re in the entire stacked structure being 1.6 atomic percent, and the thickness of the antiferromagnetic coupling layer t_{IrRe} being 0.4 nm, 0.45 nm, 0.5 nm, 0.55 nm, and 0.6 nm, and a plurality of samples were fabricated in which the Re/Ir/Re stacked layer was sandwiched above and below by 0.5 nm Co layers. FIG. 28A is a diagram illustrating a structure of the samples in Verification Experiment 8. Using a Si substrate having a thermal oxide film, a 5.0 nm Ta layer was disposed on the thermal oxide film, a 6.0 nm Ru layer was disposed on the Ta layer, a 2.0 nm Pt layer was disposed on the Ru layer, and then four layers each of 0.5 nm Co layers and 0.3 nm Pt layers were alternately disposed on the Pt layer; additionally, a 0.5 nm Co layer, a Re/Ir/Re stacked layer, and a 0.5 nm Co layer were disposed in this order; additionally, four layers each of 0.3 nm Pt layers and 0.5 nm Co layers were alternately disposed; and further a 3 nm Pt layer was disposed. The samples were then annealed at 400° C. As a result, the stacked structure became an Ir—Re alloy.

### <Verification Experiment 9>

In Verification Experiment 9, using the antiferromagnetic coupling layer as an Ir/Re/Ir stacked structure, with the atom proportion of Re in the entire stacked structure being 1.6 atomic percent, and the thickness of the antiferromagnetic coupling layer t_{IrRe} being 0.4 nm, 0.45 nm, 0.5 nm, 0.55 nm, and 0.6 nm, and a plurality of samples were fabricated in which the Ir/Re/Ir stacked layer was sandwiched above and below by 0.5 nm Co layers. FIG. 28B is a diagram illustrating a structure of the samples in Verification Experiment 9. Using a Si substrate having a thermal oxide film, a 5.0 nm Ta layer was disposed on the thermal oxide film, a 6.0 nm Ru layer was disposed on the Ta layer, a 2.0 nm Pt layer was disposed on the Ru layer, and then four layers each of 0.5 nm Co layers and 0.3 nm Pt layers were alternately disposed on the Pt layer; additionally, a 0.5 nm Co layer, an Ir/Re/Ir stacked layer, and a 0.5 nm Co layer were disposed in this order; additionally four layers each of 0.3 nm Pt layers and 0.5 nm Co layers were alternately disposed; and further a 3 nm Pt layer was disposed. The samples were then annealed at 400° C. As a result, the stacked structure became an Ir—Re alloy.

### <Comparative Experiment 3>

In Comparative Experiment 3, using the antiferromagnetic coupling layer as an Ir layer, and samples were fabricated in which the thicknesses t_{Ir} is 0.4 nm, 0.45 nm, 0.5 nm, 0.55 nm, and 0.6 nm, and the Ir layer was sandwiched above and below by 0.5 nm Co layers. FIG. 28C is a diagram illustrating a structure of the samples in Comparative Experiment 3. Using a Si substrate having a thermal oxide film, a 5.0 nm Ta layer was disposed on the thermal oxide film, a 6.0 nm Ru layer was disposed on the Ta layer, a 2.0 nm Pt layer was disposed on the Ru layer, and then four layers each of 0.5 nm Co layers and 0.3 nm Pt layers were alternately disposed on the Pt layer; additionally, a 0.5 nm Co layer, an Ir layer with a film thickness t_{Ir}, and a 0.5 nm Co layer were disposed in this order; additionally, four layers each of 0.3 nm Pt layers and 0.5 nm Co layers were alternately disposed; and further a 3 nm Pt layer was disposed. The samples were then annealed at 400° C.

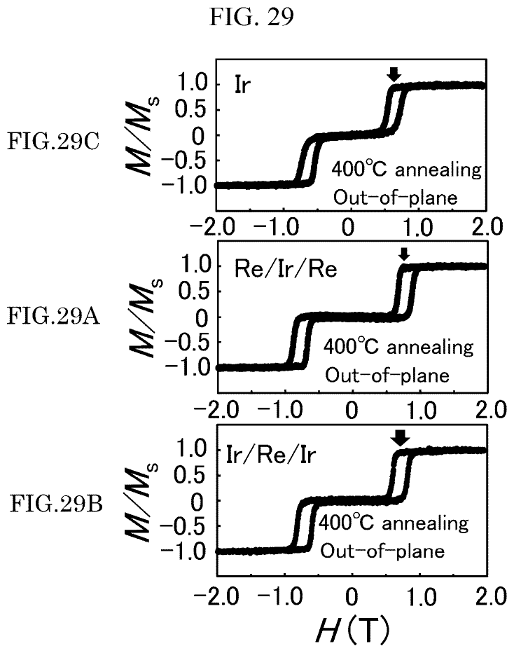

M-H curves were measured for each sample fabricated in Verification Experiments 8 and 9 and Comparative Experiment 3. FIG. 29A is the M-H curve for the sample with the Re/Ir/Re stacked layer (an Ir—Re alloy with 1.6 atomic percent Re after annealing) with a film thickness t_{IrRe} of 0.5 nm in Verification Experiment 8, FIG. 29B is the M-H curve for the sample with the stacked layer Ir/Re/Ir (an Ir—Re alloy with 1.6 atomic percent Re after annealing) with a film thickness t_{IrRe} of 0.5 nm in Verification Experiment 9, and FIG. 29C is the M-H curve for the sample with a film thickness t_{Ir} 0.55 nm of Ir in Comparative Experiment 3. The horizontal axis indicates the applied magnetic field H(T), and the vertical axis indicates M/Ms. Ms is a saturation value, and Hex is an exchange coupling magnetic field. The applied magnetic field is perpendicular to the surface (out-of-plane). Exchange coupling between the AFs was observed in all the samples at zero external magnetic field (H=0T). As shown in FIG. 29A and FIG. 29B, it was found that the samples with the Re/Ir/Re, Ir/Re/Ir stacked layer showed larger exchange coupling magnetic fields Hex than the sample with only the Ir layer.

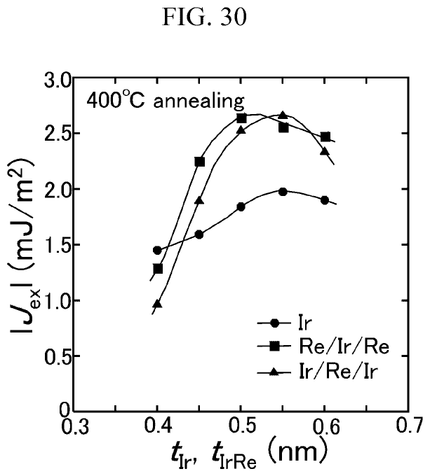

FIG. 30 plots the interlayer exchange coupling |Jₑₓ| as a function of the film thickness t_{IrRe} of the Ir—Re alloy in the samples after annealing in Verification Experiments 8 and 9 and the film thickness t_{Ir} of Ir in Sample 3 after annealing in Comparative Experiment 3. It was found that the interlayer exchange coupling |Jₑₓ| was more than approximately 1.0 (mJ/m²) for both the samples in Verification Experiment 8 and the samples in Verification Experiment 9. As shown in FIG. 30, the maximum value of the interlayer exchange coupling |Jₑₓ was almost the same for both the samples after annealing in Verification Experiment 8 and the sample after annealing in Verification Experiment 9, at approximately 2.7 (mJ/m²). This means that the strong AF coupling was observed in the samples in Verification Experiments 8 and 9, compared with the result of Comparative Experiment 3. This indicates that it is due to the mutual diffusion between Ir and Re atoms.

Furthermore, it was found that the maximum value of the interlayer exchange coupling |Jₑₓ| was much more in the range where the film thickness t_{IrRe} of the Ir—Re alloy in the sample after annealing was 0.45 nm or more and 0.6 nm or less, compared with Comparative Experiment 3.

From this, it was found that, as in Verification Experiments 8 and 9, the interlayer exchange coupling |Jₑₓ| of the antiferromagnetic coupling layer increases by about 30% when the antiferromagnetic coupling layer contains Re. These results were the same as those described with reference to FIGS. 18A, 18B, 21, and the like.

As shown in FIG. 30, for the samples in Verification Experiment 8, the maximum value of the interlayer exchange coupling |Jₑₓ| was observed at a smaller film thickness than for the samples in Verification Experiment 9 and Comparative Experiment 3.

In the embodiments of the present invention, a pin layer of a magnetoresistive effect element (MTJ element) includes a synthetic antiferromagnetic layer, therefore having strong perpendicular magnetic anisotropy and good thermal stability. Therefore, a high-density spin device can be provided. In addition, since the coupling strength between the magnetic layers in the SAF layer is strong, write errors due to back-hopping are suppressed.

An SOT-MRAM according to the embodiments of the present invention is configured to stack a recording layer, a tunnel barrier layer, and a reference layer in order on a conductive layer and include a magnetoresistive effect element (MTJ element). As the conductive layer, a synthetic antiferromagnetic layer is employed. More specifically, the conductive layer includes an antiferromagnetic coupling layer including a non-magnetic layer and an interlayer coupling layer between a first magnetic layer and a second magnetic layer. Since the interlayer coupling layer includes a layer made of an Ir—Re alloy, it has strong antiferromagnetic coupling, strong perpendicular magnetic anisotropy, and good thermal stability. In addition, the SOT-MRAM has annealing tolerance at 300° C. to 400° C.

In order to fabricate a device including each element and the like using a magnetic film according to the embodiments of the present invention, a magnetic layer is formed and then subject to heat treatment, and a pattern of a magnetoresistive effect element (MTJ element) is created to form the magnetoresistive effect element by an etching process. After a protective film is formed thereon, annealing treatment is performed at 300° C. to 400° C. to relax the stress or strain of the magnetoresistive effect element and the protective film. Since the stacked film according to the embodiments of the present invention has annealing tolerance, even after annealing treatment, the antiferromagnetically coupled magnetic layers included in the reference layer maintain perpendicular magnetic anisotropy, making it possible to perform strong pinning.

### Eleventh Embodiment

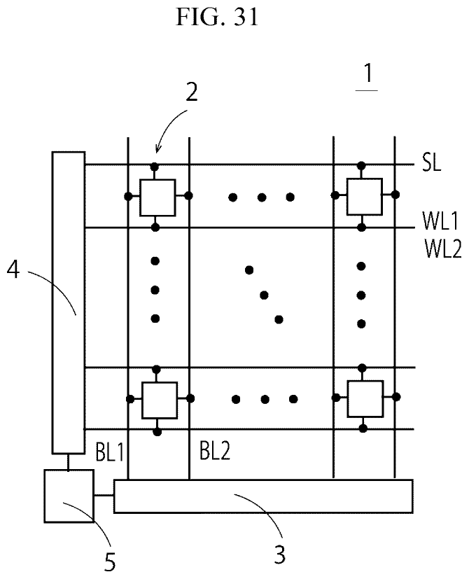

FIG. 31 is a diagram illustrating a semiconductor memory as an integrated circuit according to an eleventh embodiment of the present invention. As illustrated in FIG. 31, a semiconductor memory 1 is configured to have a plurality of memory cells 2 arranged in an array shape. The semiconductor memory 1 includes an X driver 3 and a Y driver 4 adjacent to a memory array, and a controller 5 controls the X driver 3 and the Y driver 4. The array shape of the memory cells 2 is arranged, for example, in M rows and M columns. A memory cell 2 is connected to a first bit line BL1 and a second bit line BL2 of the corresponding column and is connected to word lines WL1, WL2 and a source line SL of the corresponding row. The X driver 3 and the Y driver 4 select the memory cells 2. The memory cells 2 are constituted of a magnetoresistive effect element according to the sixth to ninth embodiments of the present invention.

### Twelfth Embodiment

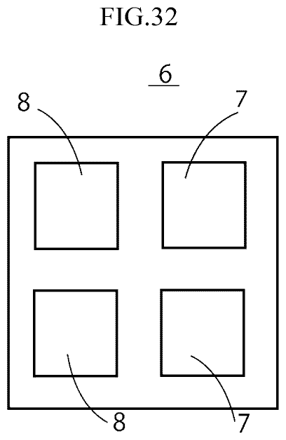

FIG. 32 is a diagram schematically illustrating a logic LSI as an integrated circuit according to a twelfth embodiment of the present invention. A logic LSI 6 includes one or a plurality of memory parts 7, one or a plurality of logic parts 8, and a peripheral circuit and an input/output circuit (not illustrated). At least any of the memory parts 7 and the logic parts 8 include a magnetoresistive effect element according to the embodiments of the present invention. In the logic LSI 6, it is not necessary that the memory parts 7 and the logic parts 8 be arranged in a flat plane as illustrated in FIG. 32. For example, the logic LSI 6 may be configured three-dimensionally to arrange the magnetoresistive effect element on a logic part.

### REFERENCE SIGNS LIST

1: semiconductor memory
6: logic LSI
10, 10A, 10B, 10C, 10D: stacked film
11, 11x: first magnetic layer
12, 12x: antiferromagnetic coupling layer
12a: interlayer coupling layer
12b, 12d: non-magnetic layer (first non-magnetic layer)
12c, 12e: second non-magnetic layer
13, 13x: second magnetic layer
20, 30, 46, 57, 67: magnetoresistive effect element
22, 34, 44, 55, 65: reference layer
23, 33, 43, 54, 64: tunnel barrier layer (barrier layer)
24, 32, 42, 53, 63: recording layer
41, 52, 62: conductive layer (wiring for SOT-MRAM)

What is claimed is:

1. A stacked film comprising:
a first magnetic layer;
an antiferromagnetic coupling layer adjacent to the first magnetic layer; and
a second magnetic layer adjacent to the antiferromagnetic coupling layer, the second magnetic layer antiferromagnetically coupled to the first magnetic layer,
wherein the antiferromagnetic coupling layer includes a layer containing an Ir—Re alloy and has an atom proportion of Re in the Ir—Re alloy of more than 0% and 12.5% or less.

2. The stacked film according to claim 1,
wherein an atom proportion of Re in the Ir—Re alloy is 10% or less.

3. The stacked film according to claim 1,
wherein an atom proportion of Re in the Ir—Re alloy is 4.5% or less.

4. The stacked film according to claim 1,
wherein a layer containing Ir and Re in the antiferromagnetic coupling layer has a thickness of more than 0.2 nm and less than 1.0 nm.

5. The stacked film according to claim 1,
wherein at least any of the first magnetic layer and the second magnetic layer includes a stacked layer of a Co layer and a Pt layer.

6. The stacked film according to claim 1,
wherein the antiferromagnetic coupling layer includes a layer containing the Ir—Re alloy and a layer containing Pt or an alloy of Pt.

7. The stacked film according to claim 1,
wherein the antiferromagnetic coupling layer includes a layer containing the Ir—Re alloy and a layer containing Ir.

8. A magnetoresistive effect element comprising:
a recording layer, a barrier layer, and a reference layer,
wherein the recording layer and the reference layer sandwich the barrier layer, and
wherein the reference layer includes the stacked film according to claim 1.

9. A magnetoresistive effect element comprising:
a recording layer, a barrier layer, and a reference layer,
wherein the recording layer and the reference layer sandwich the barrier layer, and
wherein the reference layer includes the stacked film according to claim 2.

10. A magnetoresistive effect element comprising:
a recording layer, a barrier layer, and a reference layer,
wherein the recording layer and the reference layer sandwich the barrier layer, and
wherein the reference layer includes the stacked film according to claim 4.

11. A magnetoresistive effect element comprising:
a recording layer, a barrier layer, and a reference layer,
wherein the recording layer and the reference layer sandwich the barrier layer, and
wherein the reference layer includes the stacked film according to claim 5.

12. A magnetoresistive effect element comprising:
a recording layer, a barrier layer, and a reference layer,
wherein the recording layer and the reference layer sandwich the barrier layer, and
wherein the reference layer includes the stacked film according to claim 6.

13. A magnetoresistive effect element comprising:
a recording layer, a barrier layer, and a reference layer,
wherein the recording layer and the reference layer sandwich the barrier layer, and
wherein the reference layer includes the stacked film according to claim 7.

14. A magnetoresistive effect element comprising:
a conductive layer, a recording layer, a barrier layer, and a reference layer,
wherein the conductive layer includes the stacked film according to claim 1, and
wherein the magnetoresistive effect element is configured such that a write current of a current flowing through the conductive layer causes a direction of magnetization in the recording layer to be reversed.

15. A magnetoresistive effect element comprising:
a conductive layer, a recording layer, a barrier layer, and a reference layer,
wherein the conductive layer includes the stacked film according to claim 2, and
wherein the magnetoresistive effect element is configured such that a write current of a current flowing through the conductive layer causes a direction of magnetization in the recording layer to be reversed.

16. A magnetoresistive effect element comprising:
a conductive layer, a recording layer, a barrier layer, and a reference layer,
wherein the conductive layer includes the stacked film according to claim 4, and
wherein the magnetoresistive effect element is configured such that a write current of a current flowing through the conductive layer causes a direction of magnetization in the recording layer to be reversed.

17. A magnetoresistive effect element comprising:
a conductive layer, a recording layer, a barrier layer, and a reference layer,
wherein the conductive layer includes the stacked film according to claim 5, and
wherein the magnetoresistive effect element is configured such that a write current of a current flowing through the conductive layer causes a direction of magnetization in the recording layer to be reversed.

18. A magnetoresistive effect element comprising:
a conductive layer, a recording layer, a barrier layer, and a reference layer,
wherein the conductive layer includes the stacked film according to claim 6, and
wherein the magnetoresistive effect element is configured such that a write current of a current flowing through the conductive layer causes a direction of magnetization in the recording layer to be reversed.

19. A magnetoresistive effect element comprising:
a conductive layer, a recording layer, a barrier layer, and a reference layer,
wherein the conductive layer includes the stacked film according to claim 7, and
wherein the magnetoresistive effect element is configured such that a write current of a current flowing through the conductive layer causes a direction of magnetization in the recording layer to be reversed.

20. A semiconductor memory comprising the magnetoresistive effect element according to claim 8.

21. A logic LSI comprising the magnetoresistive effect element according to claim 8.

22. A semiconductor memory comprising the magnetoresistive effect element according to claim 14.

23. A logic LSI comprising the magnetoresistive effect element according to claim 14.
